(19) United States
(12) Patent Application Publication
(10) Pub. No.: US 2026/0074626 A1
(43) Pub. Date: Mar. 12, 2026

(54) POWER CONVERSION DEVICE AND CAPACITOR DEVICE

(71) Applicant: DENSO CORPORATION, Kariya-city (JP)

(72) Inventors: Ryo MIYAZAKI, Kariya-city (JP); Yuya ASAI, Kariya-city (JP)

(73) Assignee: DENSO CORPORATION, Kariya-city (JP)

(21) Appl. No.: 19/388,157

(22) Filed: Nov. 13, 2025

Related U.S. Application Data
(63) Continuation of application No. PCT/JP2023/044444, filed on Dec. 12, 2023.

(30) Foreign Application Priority Data
May 29, 2023 (JP) 2023-087916
Dec. 5, 2023 (JP) 2023-205449

(51) Int. Cl. H02M 7/00; H01G 2/08; H01G 4/224; H01G 4/40; H02M 7/5387; H05K 7/20

(52) U.S. Cl. CPC H02M 7/003; H01G 2/08; H01G 4/224; H01G 4/40; H02M 7/5387; H05K 7/209; H05K 7/20927

(57) ABSTRACT

A power conversion device is disclosed, comprising a capacitor device positioned between an electrical component and a switch module. The capacitor device includes capacitor elements aligned in a direction different from a width direction, specifically along an arrangement direction of the electrical component and the switch module. Each capacitor element has a first electrode and a second electrode on end faces separated in the width direction. A high-potential busbar electrically connects first electrodes, the electrical component, and the switch module, while a low-potential busbar electrically connects second electrodes, the electrical component, and the switch module. High-potential and low-potential busbars are arranged to overlap the capacitor elements in a plate thickness direction. High-potential and low-potential busbars each have a first portion and a second portion, with their respective positions in the plate thickness direction specified relative to the capacitor elements.

### CROSS REFERENCE TO RELATED APPLICATIONS

The present application is a continuation application of International Patent Application No. PCT/JP2023/044444 filed on Dec. 12, 2023, which designated the U.S. and claims the benefit of priority from Japanese Patent Application No. 2023-087916 filed in Japan on May 29, 2023 and Japanese Patent Application No. 2023-205449 filed in Japan on Dec. 5, 2023. The entire disclosures of all of the above applications are incorporated herein by reference.

### TECHNICAL FIELD

The disclosure described in this specification relates to a power conversion device and a capacitor device.

### BACKGROUND

A busbar has an electrode terminal portion, a connection terminal portion, and a relay terminal portion.

### SUMMARY

According to at least one embodiment, a power conversion device includes a capacitor device that is provided between an electrical component and a switch module. The capacitor device has capacitor elements arranged in an alignment direction that is different from a width direction. The alignment direction is a direction in which the electrical component and the switch module are arranged, and each capacitor element has a first electrode and a second electrode on end faces separated in the width direction. A high-potential busbar electrically connects first electrodes of the capacitor elements, the electrical component, and the switch module. A low-potential busbar electrically connects second electrodes of the capacitor elements, the electrical component, and the switch module. The high-potential busbar and the low-potential busbar may be provided at positions overlapping the capacitor elements in a plate thickness direction that is different from the alignment direction and the width direction. The high-potential busbar may have a first high-potential portion and a second high-potential portion. The low-potential busbar may have a first low-potential portion and a second low-potential portion. The first high-potential portion may be provided farther from the capacitor elements than the first low-potential portion in the plate thickness direction. The second low-potential portion may be provided farther from the capacitor elements than the second high-potential portion in the plate thickness direction.

### BRIEF DESCRIPTION OF DRAWINGS

The details of one or more embodiments are set forth in the accompanying drawings and the description below. Other features and advantages will be apparent from the description and drawings, and from the claims.

FIG. 1 is an electrical circuit diagram illustrating an in-vehicle system.

FIG. 2 is a plan view of a power conversion device.

FIG. 3 is a cross-sectional view taken along line III-III of FIG. 2.

FIG. 4 is an exploded perspective view of a capacitor device.

FIG. 5 is a perspective view of the capacitor device.

FIG. 6 is a perspective view of a capacitor element.

FIG. 7 is a schematic diagram illustrating a part of an electric current path of the capacitor device.

FIG. 8 is a schematic diagram illustrating a part of an electric current path of the capacitor device.

FIG. 9 is a plan view of a case provided with a heat dissipation member.

FIG. 10 is a cross-sectional view taken along line X-X of FIG. 2.

FIG. 11 is a schematic diagram illustrating a manufacturing method of a busbar module.

FIG. 12 is a schematic diagram illustrating the manufacturing method of the busbar module.

FIG. 13 is a plan view of a power conversion device according to a second embodiment.

FIG. 14 is a perspective view of a capacitor device according to the second embodiment.

FIG. 15 is a schematic diagram illustrating a manufacturing method of a busbar module according to the second embodiment.

FIG. 16 is a plan view of a capacitor element according to a third embodiment.

FIG. 17 is a plan view of a capacitor device according to the third embodiment.

FIG. 18 is a plan view of a high-potential busbar according to the third embodiment.

FIG. 19 is a plan view of a low-potential busbar according to the third embodiment.

FIG. 20 is a plan view of an insulating plate according to the third embodiment.

FIG. 21 is a perspective view of a capacitor device according to a fourth embodiment.

FIG. 22 is an exploded perspective view of the capacitor device according to the fourth embodiment.

FIG. 23 is a schematic diagram illustrating a manufacturing method of a busbar module according to the fourth embodiment.

FIG. 24 is a perspective view of the capacitor device according to the fourth embodiment as seen in cross section along line XXIV-XXIV.

FIG. 25 is a cross-sectional view of a power conversion device according to the fourth embodiment.

### DETAILED DESCRIPTION

To begin with, examples of relevant techniques will be described.

A busbar has an electrode terminal portion, a connection terminal portion, and a relay terminal portion. The electrode terminal portion covers end surface electrodes of a capacitor element from above. The electrode terminal portion includes a front plate portion, a rear plate portion, and a protruding portion that protrudes upward in a rectangular wave shape between the front plate portion and rear plate portion. Connection pins on the front and rear plates are in contact with the end surface electrodes. The electrode terminal portion and the connection terminal portion are interconnected via an intermediate terminal portion. The connection terminal portion is connected to an external terminal that is connected to a power supply device.

A power conversion device according to a comparative example, heat from the capacitor element is easily dissipated through the protruding portion. However, only one of the two busbars connected to the capacitor element is cooled, so the capacitor element is cooled from only one side. As a result, heat dissipation performance of the capacitor element is insufficient, and further improvement has been required.

In contrast to the comparative example, according to a a power conversion device and a capacitor device of the present disclosure, heat dissipation performance of a capacitor element can be improved.

According to one aspect of the present disclosure, a power conversion device includes a capacitor device that is provided between an electrical component and a switch module. The capacitor device has capacitor elements arranged in an alignment direction that is different from a width direction. The alignment direction is a direction in which the electrical component and the switch module are arranged, and each capacitor element has a first electrode and a second electrode on end faces separated in the width direction. A high-potential busbar electrically connects first electrodes of the capacitor elements, the electrical component, and the switch module. A low-potential busbar electrically connects second electrodes of the capacitor elements, the electrical component, and the switch module. The high-potential busbar and the low-potential busbar are provided at positions overlapping the capacitor elements in a plate thickness direction that is different from the alignment direction and the width direction. The high-potential busbar has a first high-potential portion and a second high-potential portion. The low-potential busbar has a first low-potential portion and a second low-potential portion. The first high-potential portion is provided farther from the capacitor elements than the first low-potential portion in the plate thickness direction. The second low-potential portion is provided farther from the capacitor elements than the second high-potential portion in the plate thickness direction.

According to this configuration, the first high-potential portion of the high-potential busbar is more easily dissipated of heat than the first low-potential portion of the low-potential busbar, and the second low-potential portion of the low-potential busbar is more easily dissipated of heat than the second high-potential portion of the high-potential busbar. Heat from the capacitor elements are more readily dissipated, particularly from the first high-potential portion and the second low-potential portion. The heat dissipation effect of the capacitor element is enhanced.

Hereinafter, embodiments for carrying out the present disclosure are described with reference to the drawings. In each embodiment, parts corresponding to the elements described in the preceding embodiments are denoted by the same reference numerals, and redundant explanation may be omitted. When only a part of the configuration is described in each embodiment, the previously described other embodiments can be applied to other parts of the configuration.

It may be possible not only to combine parts the combination of which is explicitly described in an embodiment, but also to combine parts of respective embodiments the combination of which is not explicitly described if any obstacle does not especially occur in combining the parts of the respective embodiments.

### First Embodiment

### <In-Vehicle System>

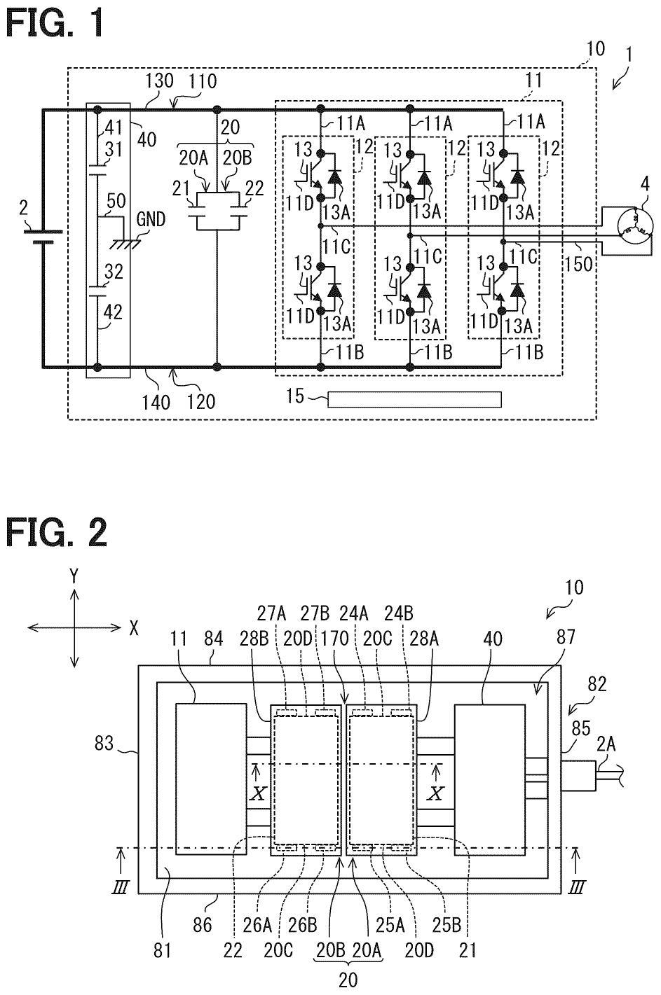

FIG. 1 is an electric circuit diagram of a power converter 10 mounted on an in-vehicle system 1. The in-vehicle system 1 includes a battery 2, a motor generator 4, and the power conversion device 10. A vehicle on which the in-vehicle system 1 is mounted is a hybrid vehicle that can run by switching between and/or combining driving force of an engine and the driving force of the motor generator 4. The engine and the motor generator 4 are interconnected via a gear mechanism.

The power conversion device 10 includes an inverter 11, a control circuit board 15, a capacitor 20, a Y-capacitor 40, a high-potential wire 110, a low-potential wire 120, an insulating plate 160, and a connecting busbar 150. The high-potential wire 110 is a conductive member connected to a positive electrode of the battery 2. The low-potential wire 120 is a conductive member connected to a negative electrode of the battery 2. The connecting busbar 150 is a conductive member that connects the inverter 11 and the motor generator 4.

The inverter 11 is connected to the high-potential wire 110 and the low-potential wire 120. The inverter 11 includes switch modules 12. Each switch module 12 includes two switching elements 13 and two diodes 13A. The two switching elements 13 are connected in series between the high-potential wire 110 and the low-potential wire 120.

Of the two switching elements 13, a collector electrode of the switching element 13 arranged on a high-potential side is connected to a high-potential input terminal 11A, which is connected to the high-potential wire 110. Of the two switching elements 13, an emitter electrode of the switching element 13 arranged on a low-potential side is connected to a low-potential input terminal 11B, which is connected to the low-potential wire 120. An anode of the diode 13A is connected to the emitter electrode of the corresponding switching element 13. A cathode of the diode 13A is connected to the collector of the corresponding switching element 13.

A motor terminal 11C, which is connected to the motor generator 4, is connected to the emitter of the high-potential side switching element 13 and to the collector of the low-potential side switching element 13. The switching elements 13 convert DC power supplied from the battery 2 into AC power that can drive the motor generator 4. The converted electric power is supplied to the motor generator 4 via the connecting busbar 150.

The control circuit board 15 performs on-off control of the switching elements 13. A control circuit for controlling the on/off of the multiple switching elements 13 is mounted on the control circuit board 15. Connection terminals 11D of the multiple switching elements 13 are connected to the control circuit board 15 by soldering. The connection terminals 11D of the switching elements 13 are electrically connected to the control circuit board 15.

The Y-capacitor 40 primarily removes noise components that have leaked from the inverter 11. The Y-capacitor 40 includes two Y-capacitor elements 31 and 32, two Y-capacitor busbars 41 and 42, and a ground busbar 50. Of the two Y-capacitor elements 31 and 32, a Y-capacitor element 31 provided on the high-potential wire 110 side is defined as a high-potential Y-capacitor element 31. Of the two Y-capacitor elements 31 and 32, a Y-capacitor element 32 provided on the low-potential wire 120 side is a low-potential Y-capacitor element 32. The Y-capacitor 40 may be referred to as an electrical component.

Of the two Y-capacitor busbars 41 and 42, a Y-capacitor busbar 41 connected to the high-potential Y-capacitor element 31 is a high-potential Y-capacitor busbar 41. The high-potential Y-capacitor element 31 is electrically connected to the high-potential wire 110 via the high-potential Y-capacitor busbar 41. Of the two Y-capacitor busbars 41 and 42, a Y-capacitor busbar 42 connected to the low-potential Y-capacitor element 32 is a low-potential Y-capacitor busbar 42. The low-potential Y-capacitor element 32 is electrically connected to the low-potential wire 120 via the low-potential Y-capacitor busbar 42.

The ground busbar 50 has a high-potential ground terminal connected to the high-potential Y-capacitor element 31, a low-potential ground terminal connected to the low-potential Y-capacitor element 32, and a ground connection terminal connected to ground. The ground busbar 50 extends so as to connect the high-potential ground terminal, the low-potential ground terminal, and the ground terminal. The ground busbar 50 is electrically connected to a body ground, such as a chassis.

The Y-capacitor elements 31 and 32 remove noise components from the inverter 11 by directing the noise leaked from the inverter 11 to the body ground via the ground busbar 50. In addition, the Y-capacitor elements 31 and 32 are capable of removing not only noise components leaking from the inverter 11, but also noise components flowing through PN wires 110 and 120. The high-potential wire 110 and the low-potential wire 120 are sometimes collectively referred to as the PN wires 110 and 120.

The capacitor 20 is electrically connected to the inverter 11 and the Y-capacitor 40 via the PN wires 110 and 120. The capacitor 20 includes a first capacitor element 21 and a second capacitor element 22. The first capacitor element 21 and the second capacitor element 22 are connected in parallel to the inverter 11 and the battery 2 via the PN wires 110 and 120. The first capacitor element 21 and the second capacitor element 22 have a first electrode 20C and a second electrode 20D. The high-potential wire 110 is connected to the first electrode 20C of the first capacitor element 21 and the first electrode 20C of the second capacitor element 22. The low-potential wire 120 is connected to the second electrode 20D of the first capacitor element 21 and the second electrode 20D of the second capacitor element 22.

The capacitor 20 primarily smooths the DC voltage supplied from the battery 2. Hereinafter, a portion of the high-potential wire 110 that connects the inverter 11, the capacitor 20, and the Y-capacitor 40 may be referred to as a high-potential busbar 130. A portion of the low-potential wire 120 that connects the inverter 11, the capacitor 20, and the Y-capacitor 40 may be referred to as a low-potential busbar 140. The insulating plate 160 is provided between the high-potential busbar 130 and the low-potential busbar 140. The insulating plate 160 is made of an insulating member such as resin, for example. The capacitor 20, the high-potential busbar 130, the low-potential busbar 140, and the insulating plate 160 may be collectively referred to as a capacitor device 170. Details of the capacitor 20 and the capacitor device 170 will be described later.

### <Mechanical Configuration of Power Converter>

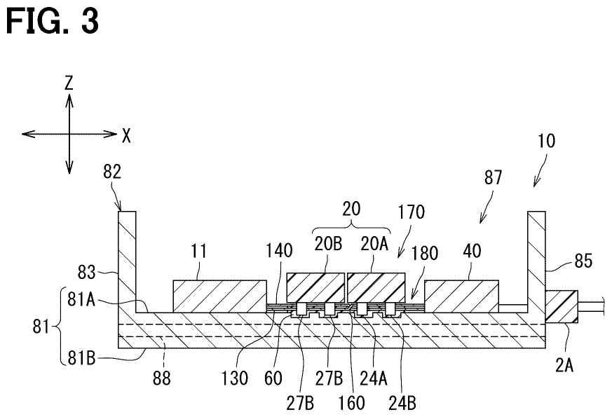

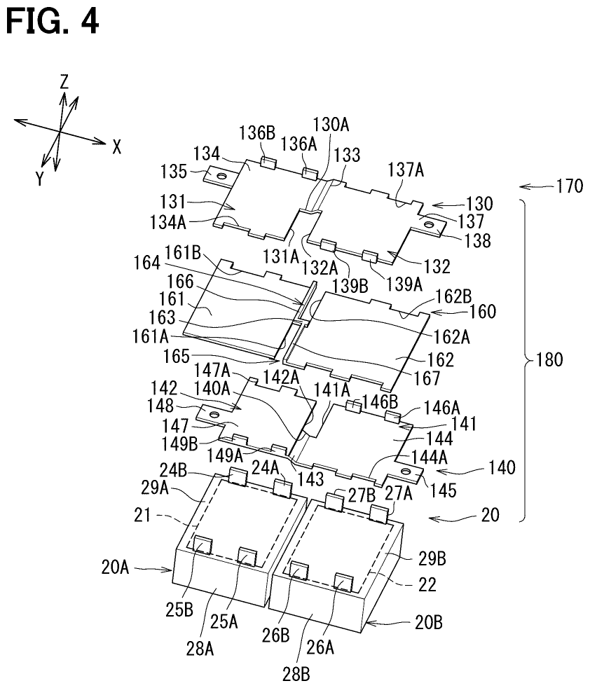

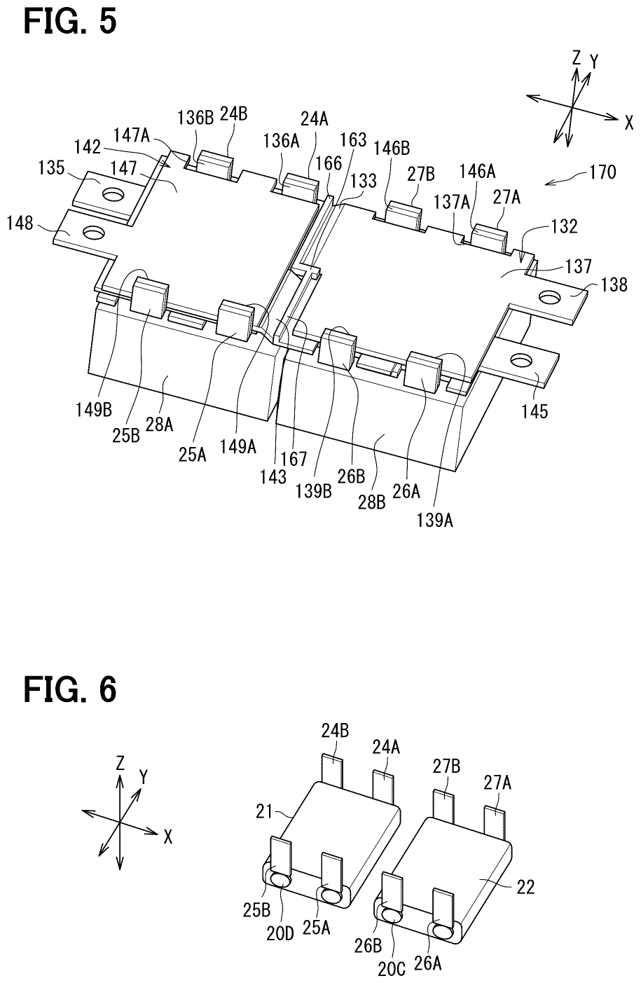

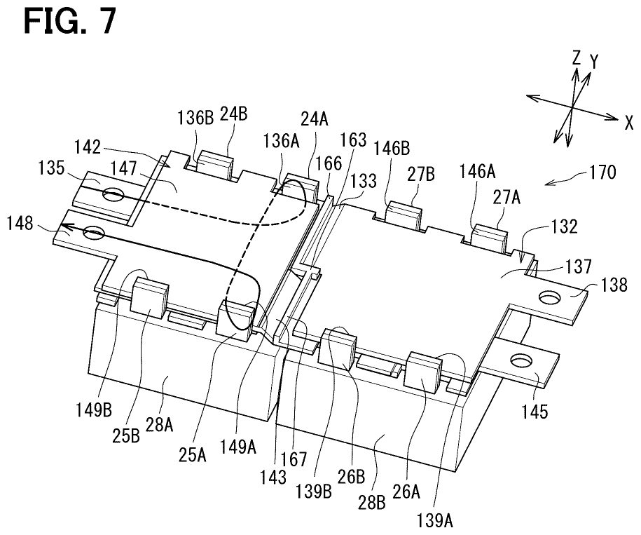

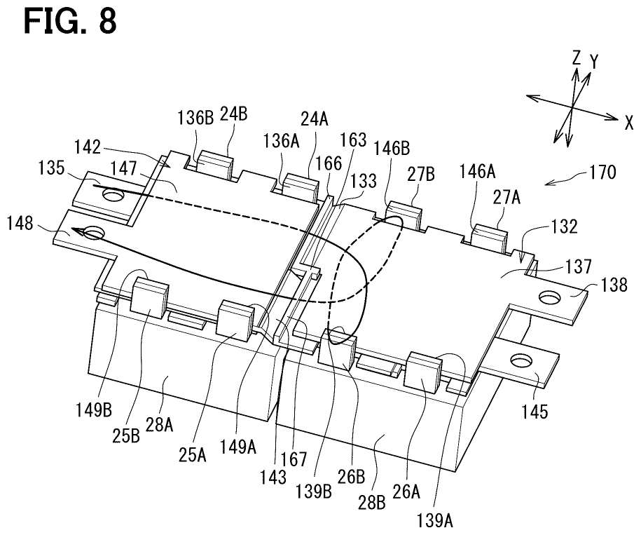

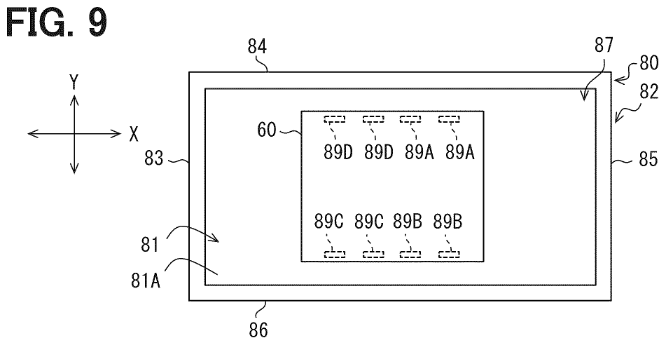

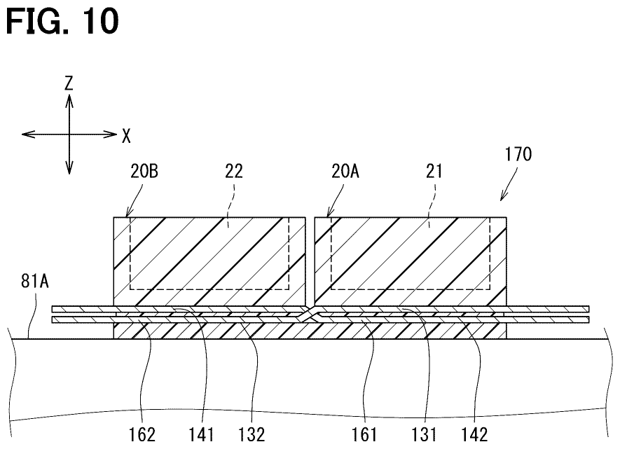

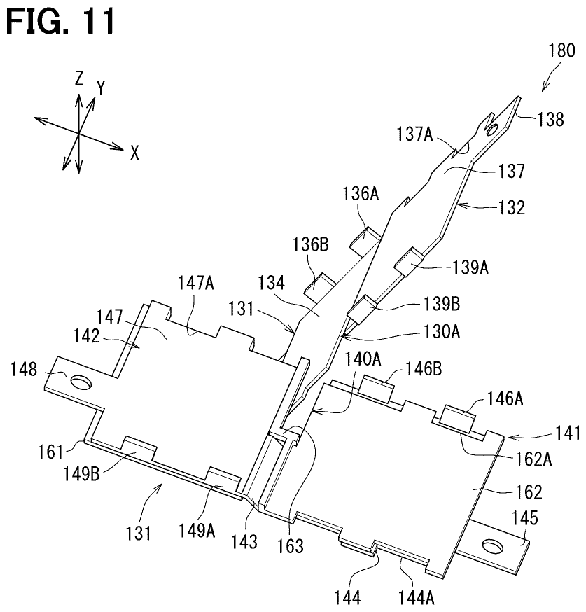

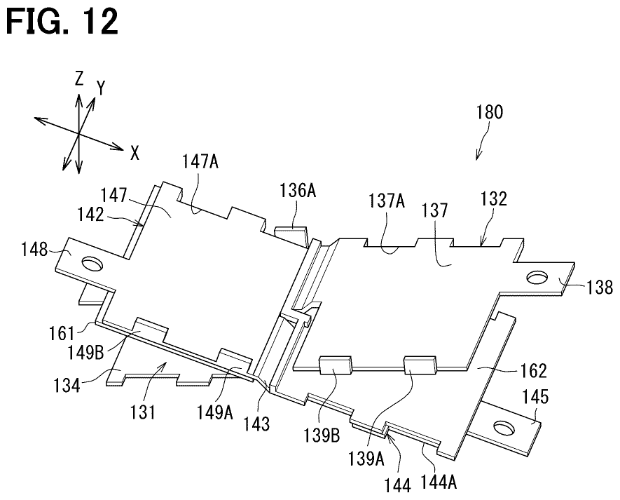

In order to explain a mechanical configuration of the power conversion device 10, the drawings will be described first. FIG. 2 is a plan view of the power conversion device 10. FIG. 3 is a cross-sectional view taken along line III-III of FIG. 2. FIG. 4 is an exploded perspective view of the capacitor device 170. FIG. 5 is a perspective view of the capacitor device 170. FIG. 6 is a perspective view of the capacitor elements 21 and 22. FIG. 7 is a schematic diagram illustrating a part of an electric current path of the capacitor device 170. FIG. 8 is a schematic diagram illustrating a part of an electric current path of the capacitor device 170. FIG. 9 is a plan view of a case 80 provided with a heat dissipation member 60. FIG. 10 is a cross-sectional view taken along line X-X in FIG. 2. FIG. 11 is a schematic diagram illustrating a manufacturing method of the busbar module 180. FIG. 12 is a schematic diagram illustrating the manufacturing method of the busbar module 180.

The power conversion device 10 includes, in addition to the components described above, the heat dissipation member 60 and the case 80. The case 80 is primarily made of a material with low thermal resistance, such as aluminum. The case 80 has a bottom portion 81 and a side wall 82. The side wall 82 protrudes from the bottom portion 81. The side wall 82 extends annularly along a peripheral edge of the bottom portion 81. A storage space 87 is defined in the case 80 by the bottom portion 81 and the side wall 82. The inverter 11, the Y-capacitor 40, the heat dissipation member 60, and the capacitor device 170 are housed in the storage space 87. Within the storage space 87 of the case 80, the inverter 11, the capacitor device 170, and the Y-capacitor 40 are arranged in series.

The side wall 82 includes a first side wall 83, a second side wall 84, a third side wall 85, and a fourth side wall 86. The first side wall 83 and the third side wall 85 are arranged along an alignment direction X, which is a direction of the inverter 11, the capacitor 20, and the Y-capacitor 40. The second side wall 84 and the fourth side wall 86 are spaced apart from each other in a width direction Y of the capacitor 20. Further, with respect to an up-down direction Z, which is orthogonal to both the alignment direction X and the width direction Y, the inverter 11, the capacitor device 170, and the Y-capacitor 40 overlap the bottom portion 81. Further, in the capacitor device 170, the PN busbars 130 and 140 overlap the capacitor 20 in the up-down direction Z. The capacitor device 170 is provided in the case 80 such that the PN busbars 130 and 140 face the bottom portion 81 in the up-down direction Z. The high-potential busbar 130 and the low-potential busbar 140 may be collectively referred to as the PN busbars 130 and 140.

The first side wall 83, the second side wall 84, the third side wall 85, and the fourth side wall 86 are arranged consecutively in a clockwise direction. The first side wall 83 faces the inverter 11 in the alignment direction X. The third side wall 85 faces the Y-capacitor 40 in the alignment direction X. The capacitor device 170 is provided between the inverter 11 and the Y-capacitor 40. As an example, a connector 2A connected to the battery 2 is provided on the third side wall 85. The electric power from the battery 2 is supplied in the order of the Y-capacitor 40, the capacitor device 170, and the inverter 11 via the connector 2A and conductive members such as harnesses.

A cooling passage 88 through which coolant flows is also formed in the bottom portion 81 of the case 80. The inverter 11, the capacitor device 170, and the Y-capacitor 40 are cooled by the coolant flowing through the cooling passage 88. As an example, the cooling passage 88 extends along the alignment direction X in which the inverter 11, the capacitor device 170, and the Y-capacitor 40 are aligned. However, the extending direction of the cooling passage 88 is not limited to this case. The cooling passage 88 may extend, for example, in a U-shape.

The heat dissipation member 60 is a member made primarily of a material that has a higher thermal conductivity than air. The heat dissipation member 60 is, for example, a heat dissipation sheet, a gap filler, a heat dissipation grease, a heat dissipation adhesive, or the like. As an example, the heat dissipation member 60 is made of a two-component curable resin. The heat dissipation member 60 has property of changing from a liquid to a solid when left at room temperature after mixing a liquid base material with a liquid curing agent. The heat dissipation member 60 is provided on the bottom portion 81. More specifically, the heat dissipation member 60 is provided in a region of the bottom portion 81 that corresponds to a projection area of the capacitor device 170 in the up-down direction Z. The heat dissipation member 60 is provided between the capacitor device 170 and the bottom portion 81. Heat from the capacitor device 170 is dissipated to the case 80 via the heat dissipation member 60.

### <Capacitor>

The capacitor 20 includes a first capacitor module 20A and a second capacitor module 20B. The first capacitor module 20A includes a first capacitor element 21, a pair of first high-potential busbars 24A and 24B, a pair of first low-potential busbars 25A and 25B, and a first capacitor case 28A. The second capacitor module 20B includes a second capacitor element 22, a pair of second high-potential busbars 26A and 26B, a pair of second low-potential busbars 27A and 27B, and a second capacitor case 28B.

In the storage space 87, the first capacitor module 20A and the second capacitor module 20B are arranged side by side in the alignment direction X. The first capacitor element 21 and the second capacitor element 22 are arranged side by side in the alignment direction X. The first capacitor element 21 is adjacent to the Y-capacitor 40 in the alignment direction X. The second capacitor element 22 is adjacent to the inverter 11 in the alignment direction X. The first capacitor element 21 is provided closer to the third side wall 85 than the second capacitor element 22. The second capacitor element 22 is provided closer to the first side wall 83 than the first capacitor element 21.

The capacitor elements 21 and 22 have a three-dimensional shape with a fixed volume. The capacitor elements 21 and 22 may be provided in a three-dimensional shape such as a cylinder, an elliptical cylinder, a polygonal prism, a cube, or a rectangular parallelepiped. The capacitor elements 21 and 22 have lengths in three orthogonal directions: the alignment direction X, the width direction Y, and the up-down direction Z. It should be noted that the term “capacitor elements 21 and 22” is a collective designation for the first capacitor element 21 and the second capacitor element 22.

The capacitor elements 21 and 22 have a first end face, a second end face, and lateral surfaces. The two end faces are provided spaced apart from each other in the width direction Y of the capacitor elements 21 and 22. The lateral surfaces connect the first end face and the second end face. The lateral surfaces extend along edges of the first end face and the second end face. The lateral surfaces can also be described as extending circumferentially along the edges of the first end face and the second end face, centered on an axis along the width direction Y. The first electrode 20C is provided on the first end face of the capacitor elements 21 and 22. The second electrode 20D is provided on the second end face of the capacitor elements 21 and 22.

In the first capacitor element 21, the first electrode 20C and the second electrode 20D are arranged side by side, separated in the width direction Y. The first electrode 20C of the first capacitor element 21 faces the second side wall 84 in the width direction Y. The second electrode 20D of the first capacitor element 21 faces the fourth side wall 86 in the width direction Y. In the second capacitor element 22, the first electrode 20C and the second electrode 20D are arranged side by side, separated in the width direction Y. The first electrode 20C of the second capacitor element 22 faces the fourth side wall 86 in the width direction Y. The second electrode 20D of the second capacitor element 22 faces the second side wall 84 in the width direction Y. The first electrode 20C of the first capacitor element 21 and the second electrode 20D of the second capacitor element 22 are arranged side by side in the alignment direction X. The second electrode 20D of the first capacitor element 21 and the first electrode 20C of the second capacitor element 22 are arranged side by side in the alignment direction X.

The pair of first high-potential busbars 24A and 24B are connected to the first electrode 20C of the first capacitor element 21. The pair of first low-potential busbars 25A and 25B are connected to the second electrode 20D of the first capacitor element 21. The pair of second high-potential busbars 26A and 26B are connected to the first electrode 20C of the second capacitor element 22. The pair of second low-potential busbars 27A and 27B are connected to the second electrode 20D of the second capacitor element 22. The pair of first high-potential busbars 24A and 24B and a pair of second low-potential busbars 27A and 27B face the second side wall 84. The pair of first low-potential busbars 25A and 25B and a pair of second high-potential busbars 26A and 26B face the fourth side wall 86.

In the present embodiment, the capacitor modules 20A and 20B have pairs of high-potential busbars 24A, 24B, 26A, and 26B, but they are not limited to being in pairs. The capacitor modules 20A and 20B have pairs of low-potential busbars 25A, 25B, 27A, and 27B, but they are not limited to being in pairs. The term “capacitor modules 20A and 20B” collectively refers to the first capacitor module 20A and the second capacitor module 20B. The term “high-potential busbars 24A and 24B, and 26A and 26B” collectively refers to the first high-potential busbars 24A and 24B and the second high-potential busbars 26A and 26B. The term “low-potential busbars 25A and 25B, and 27A and 27B” collectively refers to the first low-potential busbars 25A and 25B and the second low-potential busbars 27A and 27B.

The first high-potential busbars 24A and 24B extend in the up-down direction Z so as to move away from the first electrode 20C. The second high-potential busbars 26A and 26B extend in the up-down direction Z so as to move away from the second electrode 20D. The second high-potential busbars 26A and 26B extend in the up-down direction Z so as to move away from the first electrode 20C. The second high-potential busbars 26A and 26B extend in the up-down direction Z so as to move away from the second electrode 20D.

The first capacitor element 21, a portion of the first high-potential busbars 24A and 24B, and the first low-potential busbars 25A and 25B are housed in the first capacitor case 28A. A sealing member is filled into the first capacitor case 28A, thereby fixing the first capacitor element 21, a portion of the first high-potential busbars 24A and 24B, and a portion of the first low-potential busbars 25A and 25B in the first capacitor case 28A.

The remaining portions of the first high-potential busbars 24A and 24B, as well as the remaining portions of the first low-potential busbars 25A and 25B, are exposed from the sealing member. As a result, the first capacitor module 20A is formed. In the first capacitor case 28A, a surface on which the first high-potential busbars 24A and 24B and the first low-potential busbars 25A and 25B are exposed is defined as a first exposed surface 29A. The first high-potential busbars 24A and 24B, as well as the first low-potential busbars 25A and 25B, are exposed from the first exposed surface 29A.

The second capacitor element 22, a portion of the second high-potential busbars 26A and 26B, and a portion of the second low-potential busbars 27A and 27B are housed in the second capacitor case 28B. A sealing member is filled into the second capacitor case 28B, and the second capacitor element 22, a portion of the second high-potential busbars 26A and 26B, and a portion of the second low-potential busbars 27A and 27B are fixed to the first capacitor case 28A.

The remaining portions of the second high-potential busbars 26A and 26B, as well as the remaining portions of the second low-potential busbars 27A and 27B, are exposed from the sealing member. As a result, the second capacitor module 20B is formed. In the second capacitor case 28B, a surface on which the second high-potential busbars 26A and 26B and the second low-potential busbars 27A and 27B are exposed is defined as a second exposed surface 29B. The second high-potential busbars 26A and 26B, as well as the second low-potential busbars 27A and 27B, are exposed from the second exposed surface 29B.

The PN busbars 130 and 140, as well as the insulating plate 160, may collectively be referred to as a busbar module 180. The busbar module 180 overlaps with the first capacitor module 20A and the second capacitor module 20B in the up-down direction Z. The busbar module 180 is provided so as to cover the first exposed surface 29A of the first capacitor module 20A and the second exposed surface 29B of the second capacitor module 20B. The busbar module 180 is provided so as to extend across the two capacitor modules 20A and 20B in the alignment direction X, overlapping the first capacitor module 20A and the second capacitor module 20B in the up-down direction Z. The details of the high-potential busbar 130 and the details of the low-potential busbar 140 are described below.

### <High-Potential Busbar>

The high-potential busbar 130 is a current-carrying path on the high-potential side that electrically connects the inverter 11, the capacitor 20, and the Y-capacitor 40. The high-potential busbar 130 has a plate thickness in the up-down direction Z. The up-down direction Z may also be referred to as a plate thickness direction. The high-potential busbar 130 includes a first high-potential extension piece 131, a second high-potential extension piece 132, and a high-potential connecting piece 133. The first high-potential extension piece 131 is a part that electrically connects the first capacitor element 21 and the Y-capacitor 40. The second high-potential extension piece 132 is a part that electrically connects the second capacitor element 22 and the inverter 11. The high-potential connecting piece 133 is a part that electrically and mechanically connects the first high-potential extension piece 131 and the second high-potential extension piece 132. The high-potential connecting piece 133 is provided between the first high-potential extension piece 131 and the second high-potential extension piece 132 in the alignment direction X. The first high-potential extension piece 131 and the second high-potential extension piece 132 are connected by the high-potential connecting piece 133, so that the entire high-potential busbar 130 extends in the alignment direction X.

The first high-potential extension piece 131 is provided so as to overlap the first capacitor element 21 in the up-down direction Z. The first high-potential extension piece 131 is provided so as to overlap the first capacitor element 21 on a side where the first busbars 24 and 25 are exposed from the first exposed surface 29A. Here, the term “first busbars 24 and 25” collectively refers to the pair of first high-potential busbars 24A and 24B and the pair of first low-potential busbars 25A and 25B. The second high-potential extension piece 132 is provided so as to overlap the second capacitor element 22 in the up-down direction Z. The second high-potential extension piece 132 is provided so as to overlap the second capacitor element 22 on a side where the second busbars 26 and 27 are exposed from the second exposed surface 29B. Here, the term “second busbars 26 and 27” collectively refers to the pair of second high-potential busbars 26A and 26B and the pair of second low-potential busbars 27A and 27B.

Additionally, a first high-potential edge portion 131A of the first high-potential extension piece 131 on a side of the second high-potential extension piece 132 is partially protruding toward the second high-potential extension piece 132. A second high-potential edge portion 132A of the second high-potential extension piece 132 on a side of the first high-potential extension piece 131 is partially protruding toward the first high-potential extension piece 131. The protruding portion of the first high-potential edge portion 131A is provided extending from a center in its width direction Y toward an end on the second side wall 84 side. The protruding portion of the second high-potential edge portion 132A is provided extending from a center in its width direction Y toward an end on the second side wall 84 side. The high-potential connecting piece 133 extends so as to connect the protruding portion of the first high-potential edge portion 131A and the protruding portion of the second high-potential edge portion 132A. A first gap 130A, which is aligned with the high-potential connecting piece 133 in the width direction Y, is defined by the first high-potential extension piece 131, the second high-potential extension piece 132, and the high-potential connecting piece 133.

Further, positions of the first high-potential extension piece 131 and the second high-potential extension piece 132 differ from each other in the up-down direction Z. The first high-potential extension piece 131 is provided closer to the capacitor 20 in the up-down direction Z than the second high-potential extension piece 132. Because the positions of the first high-potential extension piece 131 and the second high-potential extension piece 132 differ in the up-down direction Z, the high-potential connecting piece 133 extends obliquely from the first high-potential extension piece 131 toward the second high-potential extension piece 132, so as to move away from the capacitor 20. A stepped shape is formed by the protruding portion of the first high-potential edge 131A, the high-potential connecting piece 133, and the protruding portion of the second high-potential edge 132A.

### <Low-Potential Busbar>

The low-potential busbar 140 is a current-carrying path on a low-potential side that electrically connects the inverter 11, the capacitor 20, and the Y-capacitor 40. The low-potential busbar 140 has a plate thickness in the up-down direction Z. The low-potential busbar 140 includes a first low-potential extension piece 141, a second low-potential extension piece 142, and a low-potential connecting piece 143. The first low-potential extension piece 141 is a part that electrically connects the second capacitor element 22 and the inverter 11. The second low-potential extension piece 142 is a part that electrically connects the first capacitor element 21 and the Y-capacitor 40. The low-potential connecting piece 143 is a part that electrically and mechanically connects the first low-potential extension piece 141 and the second low-potential extension piece 142. The low-potential connecting piece 143 is provided between the first low-potential extension piece 141 and the second low-potential extension piece 142 in the alignment direction X. The first low-potential extension piece 141 and the second low-potential extension piece 142 are connected by the low-potential connecting piece 143, and the entire low-potential busbar 140 extends in the alignment direction X.

The first low-potential extension piece 141 is provided so as to overlap the second capacitor element 22 in the up-down direction Z. The first low-potential extension piece 141 is provided so as to overlap the second capacitor element 22 on a side where the second busbars 26 and 27 are exposed from the second exposed surface 29B. The second low-potential extension piece 142 is provided so as to overlap the first capacitor element 21 in the up-down direction Z. The second low-potential extension piece 142 is provided so as to overlap the first capacitor element 21 on a side where the first busbars 24 and 25 are exposed from the first exposed surface 29A. A first low-potential edge portion 141A on the second low-potential extension piece 142 side of the first low-potential extension piece 141 partially protrudes toward the second low-potential extension piece 142 side. A second low-potential edge portion 142A on the first low-potential extension piece 141 side of the second low-potential extension piece 142 partially protrudes toward the first low-potential extension piece 141 side.

The protruding portion of the first low-potential edge portion 141A is provided extending from a center in its own width direction Y to an end on the fourth side wall 86 side. The protruding portion of the second low-potential edge portion 142A is provided extending from a center in its own width direction Y to an end on the second side wall 84 side. The low-potential connecting piece 143 extends so as to connect the protruding portion of the first low-potential edge portion 141A and the protruding portion of the second low-potential edge portion 142A. The first low-potential extension piece 141, the second low-potential extension piece 142, and the low-potential connecting piece 143 together define a second gap 140A, which is arranged alongside the low-potential connecting piece 143 in the width direction Y.

Further, positions of the first low-potential extension piece 141 and the second low-potential extension piece 142 differ from each other in the up-down direction Z. The first low-potential extension piece 141 is provided closer to the capacitor 20 in the up-down direction Z than the second low-potential extension piece 142. Because the positions of the first low-potential extension piece 141 and the second low-potential extension piece 142 differ in the up-down direction Z, the low-potential connecting piece 143 extends obliquely from the first low-potential extension piece 141 toward the second low-potential extension piece 142, so as to move away from the capacitor 20. A stepped shape is formed by the protruding portion of the first low-potential edge part 141A, the low-potential connecting piece 143, and the protruding portion of the second low-potential edge part 142A.

### <High-Potential Busbar and Low-Potential Busbar>

As described above, the first gap 130A is defined by the first high-potential extension piece 131, the second high-potential extension piece 132, and the high-potential connecting piece 133. The second gap 140A is defined by the first low-potential extension piece 141, the second low-potential extension piece 142, and the low-potential connecting piece 143. The high-potential busbar 130 has a recessed shape that is indented from the fourth side wall 86 toward the second side wall 84. The low-potential busbar 140 has a recessed shape that is indented from the second side wall 84 toward the fourth side wall 86. The low-potential connecting piece 143 passes through the first gap 130A. The high-potential connecting piece 133 passes through the second gap 140A.

As described above, the high-potential connecting piece 133 extends obliquely from the first high-potential extension piece 131 toward the second high-potential extension piece 132, slanting away from the capacitor 20. The low-potential connecting piece 143 extends obliquely from the first low-potential extension piece 141 toward the second low-potential extension piece 142, slanting away from the capacitor 20. The connecting pieces 133 and 143, which extend in an oblique direction, pass through the gaps 130A and 140A. Therefore, on the first capacitor element 21 side, the second low-potential extension piece 142 is provided at a position farther from the first capacitor element 21 in the up-down direction Z than the first high-potential extension piece 131. A distance in the up-down direction Z between the first capacitor element 21 and the second low-potential extension piece 142 is greater than a distance in the up-down direction Z between the first capacitor element 21 and the first high-potential extension piece 131. On the second capacitor element 22 side, the second high-potential extension piece 132 is provided at a position farther from the second capacitor element 22 in the up-down direction Z than the first low-potential extension piece 141. A distance in the up-down direction Z between the second capacitor element 22 and the second high-potential extension piece 132 is longer than a distance in the up-down direction Z between the second capacitor element 22 and the first low-potential extension piece 141. The PN busbars 130 and 140 extend such that the order of the high-potential busbar 130 and the low-potential busbar 140 in the up-down direction Z is reversed between the first capacitor element 21 side and the second capacitor element 22 side.

The first high-potential extension piece 131 includes a first high-potential overlapping portion 134, a Y-capacitor high-potential connection terminal 135, and a pair of first high-potential connection terminals 136A and 136B. The first high-potential overlapping portion 134 is a portion that overlaps with the first capacitor element 21 in the up-down direction Z. The first high-potential overlapping portion 134 extends along the width direction Y and the alignment direction X. The Y-capacitor high-potential connection terminal 135 is a terminal that is connected to the high-potential Y-capacitor busbar 41 of the Y-capacitor 40. The Y-capacitor high-potential connection terminal 135 is provided at an end of the first high-potential overlapping portion 134 on the third side wall 85 side, and extends away from the first high-potential overlapping portion 134. The Y-capacitor high-potential connection terminal 135 and the high-potential Y-capacitor busbar 41 are electrically and mechanically connected via a fastening member such as a bolt.

The pair of first high-potential connection terminals 136A and 136B are terminals that are connected to the pair of first high-potential busbars 24A and 24B. The pair of first high-potential connection terminals 136A and 136B are provided at an end of the first high-potential overlapping portion 134 on the second side wall 84 side. The pair of first high-potential connection terminals 136A and 136B protrude so as to extend away from the first exposed surface 29A. One of the pair of first high-potential connection terminals 136A and 136B overlaps with one of the pair of first high-potential busbars 24A and 24B in the width direction Y. The other one of the pair of first high-potential connection terminals 136A and 136B overlaps, in the width direction Y, with the other one of the pair of first high-potential busbars 24A and 24B.

The first high-potential connection terminals 136A and 136B and the first high-potential busbars 24A and 24B are electrically and mechanically connected by welding. In addition, at an end on the fourth side wall 86 side of the first high-potential overlapping portion 134, a first high-potential notch 134A is formed, through which the pair of first low-potential busbars 25A and 25B are capable of passing. The pair of first low-potential busbars 25A and 25B extend away from the first exposed surface 29A relative to the first high-potential overlapping portion 134 via the first high-potential notch 134A.

The second high-potential extension piece 132 includes a second high-potential overlapping portion 137, an inverter high-potential connection terminal 138, and a pair of second high-potential connection terminals 139A and 139B. The second high-potential overlapping portion 137 is a portion that overlaps the second capacitor element 22 in the up-down direction Z. The second high-potential overlapping portion 137 extends along the width direction Y and the alignment direction X. The inverter high-potential connection terminal 138 is a terminal that is connected to the high-potential input terminal 11A of the inverter 11. The inverter high-potential connection terminal 138 is provided at an end of the second high-potential overlapping portion 137 on the first side wall 83 side, and extends away from the second high-potential overlapping portion 137. The inverter high-potential connection terminal 138 and the high-potential input terminal 11A are electrically and mechanically connected via a fastening member such as a bolt.

The pair of second high-potential connection terminals 139A and 139B are terminals that are connected to the pair of second high-potential busbars 26A and 26B. The pair of second high-potential connection terminals 139A and 139B are provided at an end of the second high-potential overlapping portion 137 on the fourth side wall 86 side. The pair of second high-potential connection terminals 139A and 139B protrude so as to extend away from the second exposed surface 29B. One of the pair of second high-potential connection terminals 139A, 139B and one of the pair of second high-potential busbars 26A, 26B overlap each other in the width direction Y. The other one of the pair of second high-potential connection terminals 139A and 139B overlaps, in the width direction Y, with the other one of the pair of second high-potential busbars 26A and 26B.

The second high-potential connection terminals 139A and 139B and the second high-potential busbars 26A and 26B are electrically and mechanically connected by welding. Additionally, at an end on the second side wall 84 side of the second high-potential overlapping portion 137, a second high-potential notch 137A is formed, through which the pair of second low-potential busbars 27A and 27B and the pair of second low-potential connection terminals 146A and 146B are capable of passing. The pair of second low-potential busbars 27A and 27B and the pair of second low-potential connection terminals 146A and 146B extend through the second high-potential notch 137A so as to be separated from the second exposed surface 29B relative to the second high-potential overlapping portion 137.

The first low-potential extension piece 141 has a first low-potential overlapping portion 144, an inverter low-potential connection terminal 145, and a pair of second low-potential connection terminals 146A and 146B. The first low-potential overlapping portion 144 is a portion that overlaps the second capacitor element 22 in the up-down direction Z. The first low-potential overlapping portion 144 extends along the width direction Y and the alignment direction X. The inverter low-potential connection terminal 145 is a terminal that is connected to the low-potential input terminal 11B of the inverter 11. The inverter low-potential connection terminal 145 is provided at an end on the first side wall 83 side of the first low-potential overlapping portion 144 and extends away from the first low-potential overlapping portion 144. The inverter low-potential connection terminal 145 and the low-potential input terminal 11B are electrically and mechanically connected via a fastening member such as a bolt.

The pair of second low-potential connection terminals 146A and 146B are terminals that are connected to the pair of second low-potential busbars 27A and 27B. The pair of second low-potential connection terminals 146A and 146B are provided at an end on the second side wall 84 side of the first low-potential overlapping portion 144. The pair of second low-potential connection terminals 146A and 146B protrude so as to extend away from the second exposed surface 29B. One of the pair of second low-potential connection terminals 146A and 146B overlaps with one of the pair of second low-potential busbars 27A and 27B in the width direction Y. The other one of the pair of second low-potential connection terminals 146A and 146B overlaps, in the width direction Y, with the other one of the pair of second low-potential busbars 27A and 27B.

The second low-potential connection terminals 146A and 146B and the second low-potential busbars 27A and 27B are electrically and mechanically connected by welding. In addition, at an end of the first low-potential overlapping portion 144 on the fourth side wall 86 side, a second low-potential notch 144A is formed, through which the pair of second high-potential busbars 26A and 26B are capable of passing. The pair of second high-potential busbars 26A and 26B extend, via the second low-potential notch 144A, so as to be separated from the second exposed surface 29B relative to the first low-potential overlapping portion 144.

The second low-potential extension piece 142 includes a second low-potential overlapping portion 147, a Y-capacitor low-potential connection terminal 148, and a pair of first low-potential connection terminals 149A and 149B. The second low-potential overlapping portion 147 is a portion that overlaps with the first capacitor element 21 in the up-down direction Z. The second low-potential overlapping portion 147 extends along the width direction Y and the alignment direction X. The Y-capacitor low-potential connection terminal 148 is a terminal that is connected to the low-potential Y-capacitor busbar 42 of the Y-capacitor 40. The Y-capacitor low-potential connection terminal 148 is provided at an end of the second low-potential overlapping portion 147 on the third side wall 85 side, and extends away from the second low-potential overlapping portion 147. The Y-capacitor low-potential connection terminal 148 and the low-potential Y-capacitor busbar 42 are electrically and mechanically connected via a fastening member such as a bolt.

The pair of first low-potential connection terminals 149A and 149B are terminals that are connected to the pair of first low-potential busbars 25A and 25B. The pair of first low-potential connection terminals 149A and 149B are provided at an end of the second low-potential overlapping portion 147 on the fourth side wall 86 side. The pair of first low-potential connection terminals 149A and 149B protrude so as to extend away from the first exposed surface 29A. One of the pair of first low-potential connection terminals 149A, 149B overlaps in the width direction Y with one of the pair of first low-potential busbars 25A, 25B. The other one of the pair of first low-potential connection terminals 149A and 149B overlaps in the width direction Y with the other one of the pair of first low-potential busbars 25A and 25B.

The first low-potential connection terminals 149A and 149B and the pair of first low-potential busbars 25A and 25B are electrically and mechanically connected by welding. In addition, at an end on the second side wall 84 side of the second low-potential overlapping portion 147, a first low-potential notch 147A is formed through which the pair of first high-potential busbars 24A and 24B and the pair of first high-potential connection terminals 136A and 136B are capable of passing. The pair of first high-potential busbars 24A and 24B and the pair of first high-potential connection terminals 136A and 136B extend through the first low-potential notch 147A so as to be spaced apart from the first exposed surface 29A relative to the second low-potential overlapping portion 147.

It should be noted that the first high-potential overlapping portion 134 and the second high-potential overlapping portion 137 may be collectively referred to as high-potential overlapping portions 134 and 137. The first low-potential overlapping portion 144 and the second low-potential overlapping portion 147 may be collectively referred to as low-potential overlapping portions 144 and 147. The second high-potential notch 137A may be referred to as a high-potential notch. The first low-potential notch 147A may be referred to as a low-potential notch.

### <Insulating Plate>

The insulating plate 160 is provided between the high-potential busbar 130 and the low-potential busbar 140 in the up-down direction Z. The insulating plate 160 serves the role of electrically insulating the high-potential busbar 130 from the low-potential busbar 140. The insulating plate 160 includes a first piece 161, a second piece 162, and a connecting piece 163. The first piece 161 and the second piece 162 have a plate shape that extends in the width direction Y and the alignment direction X. The first piece 161 and the second piece 162 are provided spaced apart from each other in the alignment direction X. The connecting piece 163 is provided so as to connect a first edge portion 161A of the first piece 161 on a side facing the second piece 162 and a second edge portion 162A of the second piece 162 on a side facing the first piece 161.

The connecting piece 163 is provided so as to connect a central portion in the width direction Y of the first edge portion 161A and a central portion in the width direction Y of the second edge portion 162A. On the second side wall 84 side, a first gap 164 is defined by the first edge portion 161A, the connecting piece 163, and the second edge portion 162A. On the fourth side wall 86 side in the width direction Y, a second gap 165 is defined by the first edge portion 161A, the connecting piece 163, and the second edge portion 162A.

The insulating plate 160 is provided between the high-potential busbar 130 and the low-potential busbar 140 in such a manner that the high-potential connecting piece 133 passes through the first gap 164 and the low-potential connecting piece 143 passes through the second gap 165. The connecting piece 163 is provided between the high-potential connecting piece 133 and the low-potential connecting piece 143 in the width direction Y. The connecting piece 163 has a length in the up-down direction Z sufficient to electrically insulate the high-potential connecting piece 133 from the low-potential connecting piece 143.

The first piece 161 has a first protruding portion 166 that protrudes in the up-down direction Z at a location on the second side wall 84 side relative to the connecting piece 163 at the first edge portion 161A. The second piece 162 has a second protruding portion 167 that protrudes in the up-down direction Z at a location on the fourth side wall 86 side relative to the connecting piece 163 in the second piece 162. The protruding directions of the first protruding portion 166 and the second protruding portion 167 are aligned with the protruding direction of the connecting piece 163. The first protruding portion 166, the connecting piece 163, and the second protruding portion 167 are formed continuously from the same material.

On the first capacitor element 21 side, the first piece 161 is provided between the first high-potential overlapping portion 134 and the second low-potential overlapping portion 147. In the up-down direction Z, the first high-potential overlapping portion 134, the first piece 161, and the second low-potential overlapping portion 147 are stacked on the first capacitor element 21. On the second capacitor element 22 side, the second piece 162 is provided between the first low-potential overlapping portion 144 and the second high-potential overlapping portion 137. In the up-down direction Z, the first low-potential overlapping portion 144, the second piece 162, and the second high-potential overlapping portion 137 are stacked on the second capacitor element 22.

At an end of the first piece 161 on the second side wall 84 side, a first notch 161B is formed through which the first high-potential busbars 24A, 24B and the first high-potential connection terminals 136A, 136B are capable of passing. The first notch 161B overlaps with the first low-potential notch 147A in the up-down direction Z. The first high-potential busbars 24A, 24B and the first high-potential connection terminals 136A, 136B are passed through a gap formed by the overlap of the first notch 161B and the first low-potential notch 147A.

At an end of the second piece 162 on the second side wall 84 side, a second notch 162B is formed through which the second low-potential busbars 27A, 27B and the second low-potential connection terminals 146A, 146B are capable of passing. The second notch 162B overlaps with the second high-potential notch 137A in the up-down direction Z. The second low-potential busbars 27A, 27B and the second low-potential connection terminals 146A, 146B are passed through a gap formed by the overlap of the second notch 162B and the second high-potential notch 137A.

### <Current-Carrying Path>

The Y-capacitor high-potential connection terminal 135 and the Y-capacitor low-potential connection terminal 148 are connected to the battery 2 via the Y-capacitor 40. The first capacitor element 21 and the second capacitor element 22 are connected in parallel. First, an electric current path of an electric current flowing through the first capacitor element 21 will be described. In FIG. 7, the electric current path of the electric current flowing through the first capacitor element 21 is indicated by arrows. The electric current that flows into the Y-capacitor high-potential connection terminal 135 flows to the first electrode 20C of the first capacitor element 21 via the first high-potential overlapping portion 134, the first high-potential connection terminals 136A and 136B, and the first high-potential busbars 24A and 24B. In the first capacitor element 21, an electric current flows from the first electrode 20C toward the second electrode 20D. The electric current that flows into the second electrode 20D flows to the Y-capacitor low-potential connection terminal 148 via the first low-potential busbars 25A and 25B, the first low-potential connection terminals 149A and 149B, and the second low-potential overlapping portion 147. From the Y-capacitor low-potential connection terminal 148, the electric current flows to the battery 2 via the Y-capacitor 40.

Next, an electric current path of an electric current flowing into the second capacitor element 22 will be described. In FIG. 8, the electric current path of the electric current flowing into the second capacitor element 22 is indicated by arrows. The electric current that flows into the Y-capacitor high-potential connection terminal 135 flows through the first high-potential overlapping portion 134, the high-potential connecting piece 133, and the second high-potential overlapping portion 137. Then, the electric current flows to the first electrode 20C of the second capacitor element 22 via the second high-potential connection terminals 139A and 139B, and the second high-potential busbars 26A and 26B. In the second capacitor element 22, an electric current flows from the first electrode 20C toward the second electrode 20D. The electric current that flows into the second electrode 20D passes through the second low-potential busbars 27A and 27B, the second low-potential connection terminals 146A and 146B, and the first low-potential overlapping portion 144. Then, the electric current flows to the Y-capacitor low-potential connection terminal 148 via the low-potential connecting piece 143 and the second low-potential overlapping portion 147. From the Y-capacitor low-potential connection terminal 148, the electric current flows to the battery 2 via the Y-capacitor 40.

Among the electric current paths of the electric current flowing through the second capacitor element 22, the electric current path connecting the high-potential connecting piece 133 of the second high-potential extension piece 132 to the second high-potential connection terminals 139A and 139B may be referred to as a first path. The electric current path connecting the second low-potential connection terminals 146A and 146B and the low-potential connecting piece 143 in the first low-potential extension piece 141 may be referred to as a second path. When viewed from the up-down direction Z, a portion of the first path and a portion of the second path intersect. It can also be said that a portion of the first path and a portion of the second path run parallel to each other. In the portion where the first path and the second path run parallel to each other, a magnetic field generated around the first path and a magnetic field generated around the second path cancel each other out.

### <Cooling of Capacitor Device>

The bottom portion 81 of the case 80 has a length in the width direction Y, the alignment direction X, and the up-down direction Z. The bottom portion 81 has a front surface 81A and a rear surface 81B that are spaced apart in the up-down direction Z. The cooling passage 88 is formed between the front surface 81A and the rear surface 81B of the bottom portion 81. The inverter 11, the Y-capacitor 40, and the capacitor device 170 are provided on the front surface 81A. The capacitor device 170 is provided on the bottom portion 81 such that the second high-potential overlapping portion 137 and the second low-potential overlapping portion 147 overlap with the front surface 81A in the up-down direction Z.

In addition, recesses 89 that are recessed from the front surface 81A toward the rear surface 81B are formed in the bottom portion 81. The recesses 89 serve as housing portions for accommodating busbars and connection terminals. The recesses 89 include a pair of first recesses 89A, a pair of second recesses 89B, a pair of third recesses 89C, and a pair of fourth recesses 89D. The pair of first high-potential connection terminals 136A and 136B, as well as the pair of first high-potential busbars 24A and 24B, are accommodated in the pair of first recesses 89A. The pair of first low-potential connection terminals 149A and 149B, as well as the pair of first low-potential busbars 25A and 25B, are accommodated in the pair of second recesses 89B. The pair of second high-potential connection terminals 139A and 139B, as well as the pair of second high-potential busbars 26A and 26B, are accommodated in the pair of third recesses 89C. The pair of second low-potential connection terminals 146A and 146B, as well as the pair of second low-potential busbars 27A and 27B, are accommodated in the pair of fourth recesses 89D.

The heat dissipation member 60 is provided over the entire region projected in the up-down direction Z onto the bottom portion 81 of the capacitor device 170. The heat dissipation member 60 is a two-component curable resin that hardens when left at room temperature. During manufacturing, the heat dissipation member 60 is in a liquid state. During manufacturing, the heat dissipation member 60 is applied to the surface 81A. When the heat dissipation member 60 is applied to the surface 81A, the heat dissipation member 60 enters the recesses 89 due to gravity and other factors. The heat dissipation member 60 comes into contact with surfaces of the recesses 89. The heat dissipation member 60 provided in the recesses 89 comes into contact with the busbar and the connection terminal.

The capacitor device 170 is provided on the bottom portion 81 such that the second high-potential overlapping portion 137 and the second low-potential overlapping portion 147 overlap with the front surface 81A in the up-down direction Z. The second low-potential overlapping portion 147 is provided closer to the surface 81A than the first high-potential overlapping portion 134. The second high-potential overlapping portion 137 is provided closer to the surface 81A than the first low-potential overlapping portion 144. Therefore, the second high-potential overlapping portion 137 and the second low-potential overlapping portion 147 are in contact with the heat dissipation member 60 on the surface 81A side.

### <Manufacturing Method>

The capacitor device 170 and a manufacturing method of the power conversion device 10 will be described. First, the manufacturing method of the capacitor device 170 will be described. Two capacitor elements 21 and 22, two capacitor cases 28A and 28B, a sealing member, first busbars 24 and 25, and second busbars 26 and 27 are prepared.

The pair of first high-potential busbars 24A and 24B are soldered to the first electrode 20C of the first capacitor element 21. The pair of first low-potential busbars 25A and 25B are soldered to the second electrode 20D of the first capacitor element 21. The first capacitor element 21 is housed in the first capacitor case 28A. The sealing member is filled into the storage space of the first capacitor case 28A. Accordingly, the first capacitor element 21, the pair of first high-potential busbars 24A and 24B, and the pair of first low-potential busbars 25A and 25B are fixed to the first capacitor case 28A via the sealing member. The pair of first high-potential busbars 24A and 24B, and the pair of first low-potential busbars 25A and 25B are exposed from the first exposed surface 29A. The description is omitted for the second capacitor module 30B, as it is manufactured in the same manner as the first capacitor module 20A.

Next, a busbar module 180 is assembled using the high-potential busbar 130, the low-potential busbar 140, and the insulating plate 160. First, the low-potential busbar 140 and the insulating plate 160 are overlapped such that the first piece 161 overlaps a rear surface of the second low-potential overlapping portion 147, and the second piece 162 overlaps the front surface of the first low-potential overlapping portion 144. Next, the first gap 130A of the high-potential busbar 130 is passed through the low-potential connecting piece 143 and the connecting piece 163. Next, the high-potential busbar 130 is brought closer to the low-potential busbar 140 by twisting the high-potential busbar 130 around the first gap 130A. While passing the first high-potential connection terminals 136A and 136B through the first low-potential notch 147A, the first high-potential overlapping portion 134 is overlapped on the rear side of the first piece 161. While passing the second low-potential connection terminals 146A and 146B through the second high-potential notch 137A, the second high-potential overlapping portion 137 is overlapped on the front surface side of the second piece 162.

Next, the heat dissipation member 60 is applied to the bottom portion 81 of the case 80. The heat dissipation member 60 is applied to the bottom portion 81 so as to cover the projected area of the capacitor device 170 on the bottom portion 81 and the recess 89. Since the heat dissipation member 60 is in a liquid state, the heat dissipation member 60 enters the recess 89 due to gravity and other forces. In the recess 89, an adhesion area of the heat dissipation member 60 to the bottom portion 81 increases. Next, the capacitor device 170 is brought closer to the bottom portion 81. The second high-potential overlapping portion 137 and the second low-potential overlapping portion 147 are brought into contact with the heat dissipation member 60.

The pair of first high-potential connection terminals 136A and 136B, and the pair of first high-potential busbars 24A and 24B are inserted into the pair of first recesses 89A. The pair of first high-potential connection terminals 136A and 136B, and the pair of first high-potential busbars 24A and 24B are brought into contact with the heat dissipation member 60. The pair of first low-potential connection terminals 149A and 149B, and the pair of first low-potential busbars 25A and 25B are inserted into the pair of second recesses 89B. The pair of first low-potential connection terminals 149A and 149B, and the pair of first low-potential busbars 25A and 25B are brought into contact with the heat dissipation member 60.

The pair of second high-potential connection terminals 139A and 139B, and the pair of second high-potential busbars 26A and 26B are inserted into the pair of third recesses 89C. The pair of second high-potential connection terminals 139A and 139B, and the pair of second high-potential busbars 26A and 26B are brought into contact with the heat dissipation member 60. The pair of second low-potential connection terminals 146A and 146B, and the pair of second low-potential busbars 27A and 27B are inserted into the pair of fourth recesses 89D. The pair of second low-potential connection terminals 146A and 146B, and the pair of second low-potential busbars 27A and 27B are brought into contact with the heat dissipation member 60.

Finally, the Y-capacitor 40 is arranged between the capacitor device 170 and the third side wall 85 in the storage space 87 of the case 80. The inverter 11 is arranged between the capacitor device 170 and the first side wall 83 in the storage space 87 of the case 80. The inverter 11 is electrically and mechanically connected to the inverter high-potential connection terminal 138 and the inverter low-potential connection terminal 145. The Y-capacitor 40 is electrically and mechanically connected to the Y-capacitor high-potential connection terminal 135 and the Y-capacitor low-potential connection terminal 148. In this manner, the power conversion device 10 is manufactured.

### <Actions and Effects>

The power conversion device 10 includes the capacitor device 170. The capacitor device 170 is provided between the Y-capacitor 40 and the inverter 11. The first capacitor element 21 and the second capacitor element 22 have electrodes on end faces that are separated in the width direction Y. The first electrode 20C is provided on the first end faces of the capacitor elements 21 and 22. The second electrode 20D is provided on the second end faces of the capacitor elements 21 and 22. The first capacitor element 21 and the second capacitor element 22 are arranged side by side in the alignment direction X.

The high-potential busbar 130 electrically connects the Y-capacitor 40, the first electrodes 20C of the capacitor elements 21 and 22, and the inverter 11. The low-potential busbar 140 electrically connects the Y-capacitor 40, the second electrodes 20D of the capacitor elements 21 and 22, and the inverter 11. The high-potential busbar 130 and the low-potential busbar 140 overlap the capacitor elements 21 and 22 in the up-down direction Z. The second high-potential extension piece 132 of the high-potential busbar 130 is provided farther from the capacitor element 22 in the up-down direction Z than the first low-potential extension piece 141 of the low-potential busbar 140. The second low-potential extension piece 142 of the low-potential busbar 140 is provided farther from the capacitor element 21 in the up-down direction Z than the first high-potential extension piece 131 of the high-potential busbar 130. The second high-potential extension piece 132 corresponds to a first high-potential portion. The first low-potential extension piece 141 corresponds to a first low-potential portion. The second low-potential extension piece 142 corresponds to a second low-potential portion. The first high-potential extension piece 131 corresponds to a second high-potential portion.

Accordingly, the second high-potential extension piece 132 is more likely to dissipate heat than the first low-potential extension piece 141. The second low-potential extension piece 142 is more likely to dissipate heat than the first high-potential extension piece 131. The heat from the capacitor elements 21 and 22 is more easily dissipated to the outside from a part of the high-potential busbar 130 and the remainder of the low-potential busbar 140. Since the heat from the capacitor elements 21 and 22 is easily dissipated from both the high-potential busbar 130 and the low-potential busbar 140, the heat dissipation efficiency of the capacitor elements 21 and 22 is improved. The output of the inverter 11 can be increased.

The high-potential busbar 130 includes the first high-potential extension piece 131, the second high-potential extension piece 132, and the high-potential connecting piece 133. The first high-potential extension piece 131 and the second high-potential extension piece 132 are positioned at different locations in the up-down direction Z. The high-potential connecting piece 133 connects a portion of the first high-potential extension piece 131 and a portion of the second high-potential extension piece 132 in the up-down direction Z. The high-potential connecting piece 133 is arranged in the width direction Y alongside the first gap 130A, which is between the remaining portion of the first high-potential extension piece 131 and the remaining portion of the second high-potential extension piece 132.

The low-potential busbar 140 includes the first low-potential extension piece 141, the second low-potential extension piece 142, and the low-potential connecting piece 143. The first low-potential extension piece 141 and the second low-potential extension piece 142 are positioned at different locations in the up-down direction Z. The low-potential connecting piece 143 connects a portion of the first low-potential extension piece 141 and a portion of the second low-potential extension piece 142 in the up-down direction Z. The low-potential connecting piece 143 is arranged in the width direction Y alongside the second gap 140A, which is between the remaining portion of the first low-potential extension piece 141 and the remaining portion of the second low-potential extension piece 142. The low-potential connecting piece 143 passes through the first gap 130A. The high-potential connecting piece 133 passes through the second gap 140A. While keeping the width direction Y compact, it is possible to enhance the heat dissipation effect of the capacitor elements 21 and 22.

The first high-potential extension piece 131 and the second low-potential extension piece 142 overlap the first capacitor element 21 in the up-down direction Z. In the up-down direction Z, the second low-potential extension piece 142 is provided farther from the first capacitor element 21 than the first high-potential extension piece 131. The first low-potential extension piece 141 and the second high-potential extension piece 132 overlap the second capacitor element 22 in the up-down direction Z. In the up-down direction Z, the second high-potential extension piece 132 is provided farther from the second capacitor element 22 than the first low-potential extension piece 141. While keeping the capacitor device 170 to a size approximately corresponding to the width direction Y of the capacitor elements 21 and 22, the heat dissipation effect of the capacitor elements 21 and 22 can be enhanced.

The first capacitor element 21 and the second capacitor element 22 are arranged side by side in the alignment direction X. The first electrode 20C of the first capacitor element 21 and the second electrode 20D of the second capacitor element 22 are arranged side by side in the alignment direction X. The second electrode 20D of the first capacitor element 21 and the first electrode 20C of the second capacitor element 22 are arranged side by side in the alignment direction X. The first high-potential extension piece 131 and the second low-potential extension piece 142 are connected to the battery 2 via the Y-capacitor 40.

The electric current flowing through the first high-potential extension piece 131 flows to the first electrode 20C of the second capacitor element 22 via the high-potential connecting piece 133 and the second high-potential extension piece 132. In the second capacitor element 22, the electric current flows from the first electrode 20C to the second electrode 20D. The electric current that has flowed into the second electrode 20D flows to the Y-capacitor 40 via the first low-potential extension piece 141, the first low-potential overlapping portion 144, and the second low-potential extension piece 142. The electric current flows to the battery 2 via the Y-capacitor 40.

When viewed from the up-down direction Z, the electric current path flowing through the second high-potential extension piece 132 and the current path flowing through the first low-potential extension piece 141 intersect. It can also be said that a portion of the electric current path flowing through the second high-potential extension piece 132 runs in parallel with a portion of the electric current path flowing through the first low-potential extension piece 141. Therefore, the magnetic field generated around the electric current path flowing through the second high-potential extension piece 132 and the magnetic field generated around the current path flowing through the first low-potential extension piece 141 cancel each other out. Accordingly, it is possible to suppress an increase in the inductance of the electric current path flowing from the positive electrode of the battery 2 to the negative electrode of the battery 2 via the capacitor elements 21 and 22.

The power conversion device 10 further includes the case 80 and the heat dissipation member 60. The case 80 houses the inverter 11, the Y-capacitor 40, and the capacitor device 170. The heat dissipation member 60 is provided on the bottom portion 81 of the case 80. The cooling passage 88 through which the coolant flows to cool the capacitor device 170 is provided inside the bottom portion 81. The capacitor device 170 is provided in the case 80 such that the high-potential busbar 130 and the low-potential busbar 140 face the bottom portion 81 in the up-down direction Z. The second high-potential extension piece 132 and the second low-potential extension piece 142 are in contact with the heat dissipation member 60. Accordingly, the high-potential busbar 130 and the low-potential busbar 140 are actively cooled. The capacitor elements 21 and 22 connected to the high-potential busbar 130 and the low-potential busbar 140 are efficiently dissipated of heat.

The first high-potential extension piece 131 has the first high-potential overlapping portion 134 and the first high-potential connection terminals 136A and 136B. The first high-potential overlapping portion 134 overlaps the first capacitor element 21 in the up-down direction Z. The first high-potential connection terminals 136A and 136B are provided at the ends in the width direction Y and are electrically connected to the first electrode 20C of the first capacitor element 21. The first high-potential connection terminals 136A and 136B protrude so as to extend away from the first high-potential overlapping portion 134. The second high-potential extension piece 132 has the second high-potential overlapping portion 137 and the second high-potential connection terminals 139A and 139B. The second high-potential overlapping portion 137 overlaps the second capacitor element 22 in the up-down direction Z. The second high-potential connection terminals 139A and 139B are provided at the ends in the width direction Y and are electrically connected to the first electrode 20C of the second capacitor element 22. The second high-potential connection terminals 139A and 139B protrude so as to extend away from the second high-potential overlapping portion 137.

The first low-potential extension piece 141 has the first low-potential overlapping portion 144 and the second low-potential connection terminals 146A and 146B. The first low-potential overlapping portion 144 overlaps the second capacitor element 22 in the up-down direction Z. The second low-potential connection terminals 146A and 146B are provided at the ends in the width direction Y and are electrically connected to the second electrode 20D of the second capacitor element 22. The second low-potential connection terminals 146A and 146B protrude so as to extend away from the first low-potential overlapping portion 144. The second low-potential extension piece 142 has the second low-potential overlapping portion 147 and the first low-potential connection terminals 149A and 149B. The second low-potential overlapping portion 147 overlaps the first capacitor element 21 in the up-down direction Z. The first low-potential connection terminals 149A and 149B are provided at the ends in the width direction Y and are electrically connected to the second electrode 20D of the first capacitor element 21. The first low-potential connection terminals 149A and 149B protrude so as to extend away from the second low-potential overlapping portion 147.

The pair of first recesses 89A, in which the pair of first high-potential connection terminals 136A and 136B are housed, is provided in the bottom portion 81. The pair of second recesses 89B, in which the pair of second high-potential connection terminals 139A and 139B are housed, is provided in the bottom portion 81. The pair of third recesses 89C, in which the pair of first low-potential connection terminals 149A and 149B are housed, is provided in the bottom portion 81. The pair of fourth recesses 89D, in which the pair of second low-potential connection terminals 146A and 146B are housed, is provided in the bottom portion 81. The heat dissipation member 60 is provided inside the first recess 89A, the second recess 89B, the third recess 89C, and the fourth recess 89D.

The first recess 89A and the second recess 89B may collectively be referred to as high-potential recesses 89A and 89B. The first high-potential connection terminals 136A and 136B and the second high-potential connection terminals 139A and 139B may collectively be referred to as high-potential connection terminals 136A, 136B, 139A, and 139B. The high-potential connection terminals 136A, 136B, 139A, and 139B are in contact with the heat dissipation member 60 inside the high-potential recesses 89A and 89B.

The third recess 89C and the fourth recess 89D may collectively be referred to as low-potential recesses 89C and 89D. The first low-potential connection terminals 149A and 149B and the second low-potential connection terminals 146A and 146B may collectively be referred to as low-potential connection terminals 146A, 146B, 149A, and 149B. The low-potential connection terminals 146A, 146B, 149A, and 149B are in contact with the heat dissipation member 60 inside the low-potential recesses 89C and 89D. Accordingly, the heat dissipation performance of the high-potential busbar 130 and the low-potential busbar 140 is improved. The capacitor elements 21 and 22 are efficiently cooled.

### Second Embodiment

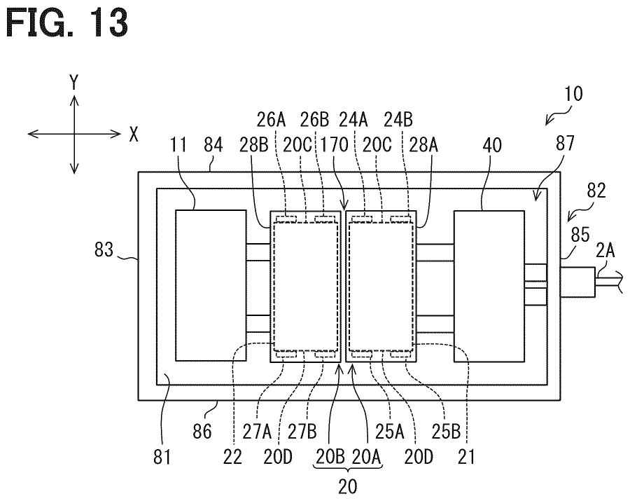

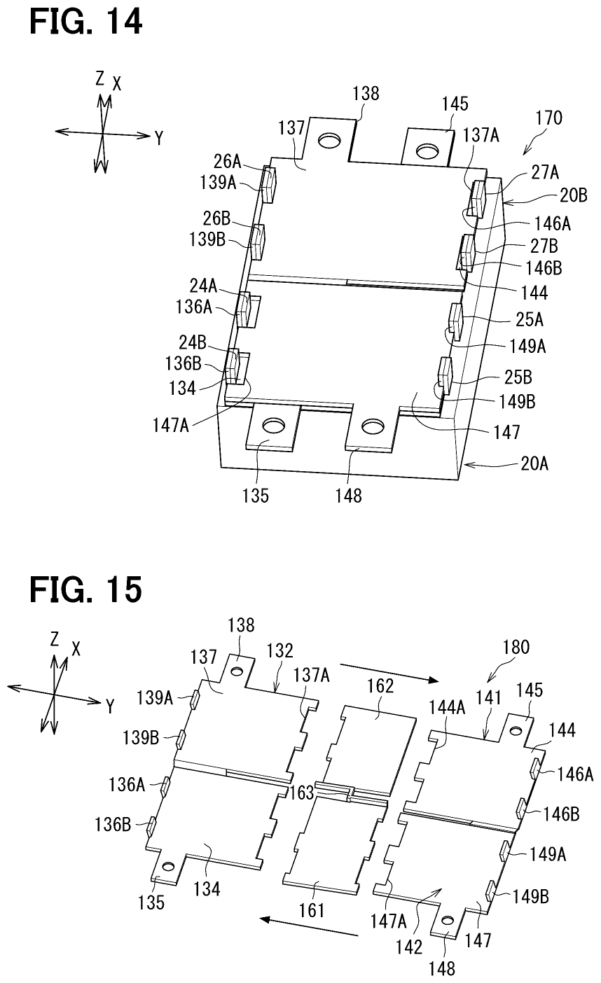

Next, a second embodiment will be described. FIG. 13 is a plan view of a power conversion device 10 according to the second embodiment. FIG. 14 is a perspective view of a capacitor device 170 according to the second embodiment. FIG. 15 is a schematic diagram illustrating a manufacturing method of a busbar module 180 according to the second embodiment. Since the second embodiment includes components common to the first embodiment, only the components that differ from the first embodiment will be described below. Components not described below are the same as those in the first embodiment. In the second embodiment, a first electrode 20C of a first capacitor element 21 and a first electrode 20C of a second capacitor element 22 are arranged side by side in the alignment direction X. A second electrode 20D of the first capacitor element 21 and a second electrode 20D of the second capacitor element 22 are arranged side by side in the alignment direction X.

A pair of first high-potential connection terminals 136A and 136B are provided at an end on a second side wall 84 side of a first high-potential overlapping portion 134. A pair of second high-potential connection terminals 139A and 139B are provided at an end on the second side wall 84 side of a second high-potential overlapping portion 137. A pair of second low-potential connection terminals 146A and 146B are provided at an end on the fourth side wall 86 side of a first low-potential overlapping portion 144. A pair of first low-potential connection terminals 149A and 149B are provided at an end on the fourth side wall 86 side of a second low-potential overlapping portion 147.

A Y-capacitor high-potential connection terminal 135 is provided at an end on the third side wall 85 side of the first high-potential overlapping portion 134 and extends away from the first high-potential overlapping portion 134. The Y-capacitor high-potential connection terminal 135 and a high-potential Y-capacitor busbar 41 are electrically and mechanically connected via a fastening member such as a bolt. A Y-capacitor low-potential connection terminal 148 is provided at the end on the third side wall 85 side of the second low-potential overlapping portion 147 and extends away from the second low-potential overlapping portion 147. The Y-capacitor low-potential connection terminal 148 and a low-potential Y-capacitor busbar 42 are electrically and mechanically connected via a fastening member such as a bolt.

In the second embodiment, a pair of second high-potential notches 137A is provided at the end on the fourth side wall 86 side of the second high-potential overlapping portion 137. The pair of second high-potential notches 137A accommodates a pair of second low-potential busbars 27A and 27B, as well as the second low-potential connection terminals 146A and 146B, passing through them. Through the pair of second high-potential notches 137A, the pair of second low-potential busbars 27A and 27B, as well as the second low-potential connection terminals 146A and 146B, extend away from a second exposed surface 29B relative to the second high-potential overlapping portion 137.

A pair of first low-potential notches 147A is provided at the end on the second side wall 84 side of the second low-potential overlapping portion 147. A pair of first high-potential busbars 24A and 24B, as well as first high-potential connection terminals 136A and 136B, pass through the pair of first low-potential notches 147A. Through the pair of first low-potential notches 147A, the pair of first high-potential busbars 24A and 24B, as well as the first high-potential connection terminals 136A and 136B, extend away from a first exposed surface 29A relative to the second low-potential overlapping portion 147.

When manufacturing the busbar module 180 of the second embodiment, unlike the first embodiment, it is possible to insert the second low-potential connection terminals 146A and 146B through the second high-potential notch 137A by moving the high-potential busbar 130 along the width direction Y. By moving the low-potential busbar 140 along the width direction Y, the first high-potential connection terminals 136A and 136B can be inserted through the first low-potential notch 147A. Unlike the first embodiment, it is not necessary to twist the high-potential busbar 130 and the low-potential busbar 140 when overlapping them. The busbar module 180 can be assembled simply by sliding the high-potential busbar 130 and the low-potential busbar 140. Therefore, manufacturability is improved.

### Third Embodiment

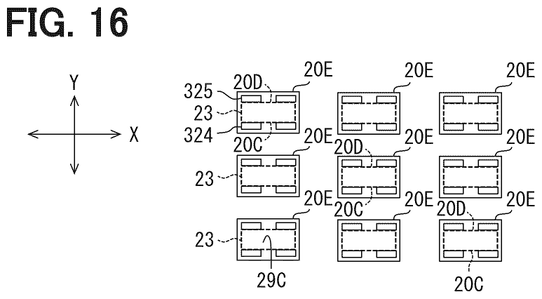

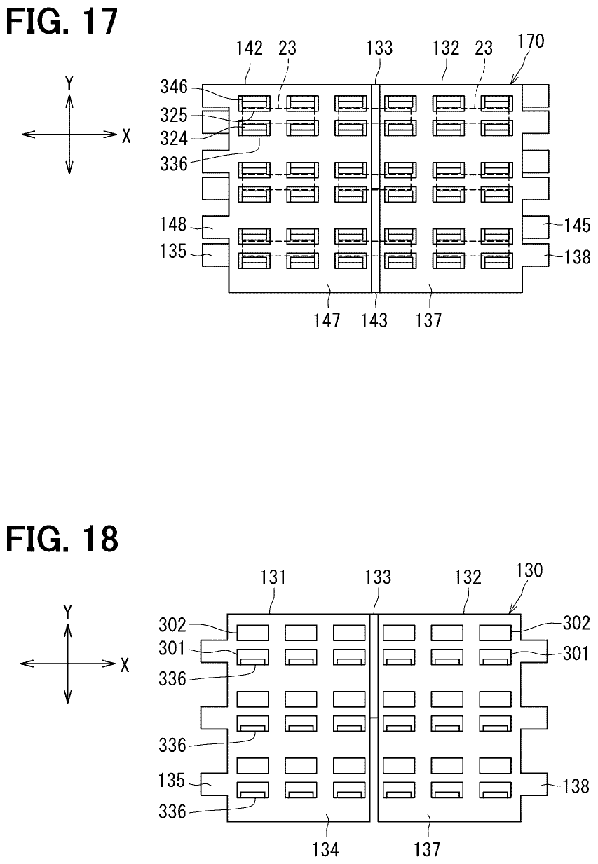

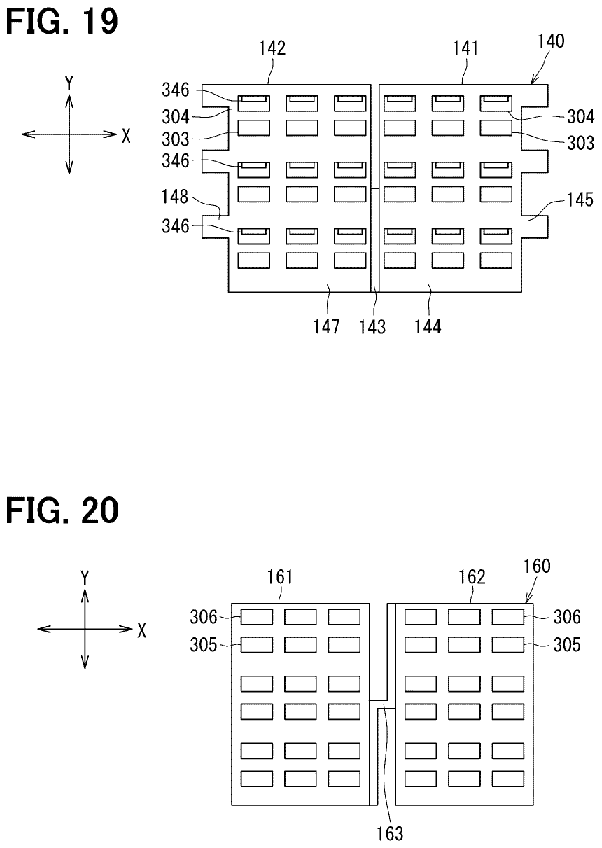

Next, a third embodiment will be described. FIG. 16 is a plan view of a third capacitor element 23 according to the third embodiment. FIG. 17 is a plan view of a capacitor device 170 according to the third embodiment. FIG. 18 is a plan view of a high-potential busbar 130 according to the third embodiment. FIG. 19 is a plan view of a low-potential busbar 140 according to the third embodiment. FIG. 20 is a plan view of an insulating plate 160 according to the third embodiment. Since the third embodiment includes components common to the first embodiment, only the components differing from the first embodiment will be described below. Components not described below are the same as those in the first embodiment. In the third embodiment, nine third capacitor modules 20E are provided in a manner arranged in three rows and three columns in the alignment direction X and the width direction Y. The number of third capacitor modules 20E is not limited to nine.

The configuration of the third capacitor module 20E is identical to that of the first capacitor module 20A or the second capacitor module 20B. The third capacitor module 20E includes a third capacitor element 23. In the third embodiment, in each row, the first electrodes 20C of the three third capacitor elements 23 are aligned in the alignment direction X. In each row, the second electrodes 20D of the three third capacitor elements 23 are aligned in the alignment direction X.

As one example, in a single third capacitor module 20E, the second electrode 20D is provided on the second side wall 84 side. The first electrode 20C is provided on the fourth side wall 86 side. In a single third capacitor module 20E, a pair of high-potential busbars 324 is provided on the first electrode 20C. In a single third capacitor module 20E, a pair of low-potential busbars 325 is provided on the second electrode 20D. Six high-potential busbars 324 are arranged in a row in the alignment direction X. Six low-potential busbars 325 are arranged in a row in the alignment direction X. The busbar module 180 is provided on a third exposed surface 29C of the third capacitor module 20E.

The first high-potential extension piece 131 is provided so as to overlap in the up-down direction Z with the third side wall side half of the three third capacitor elements 23 arranged in the first row and the three third capacitor elements 23 arranged in the second row. The second high-potential extension piece 132 is provided so as to overlap in the up-down direction Z with the first side wall side half of the three third capacitor elements 23 arranged in the third row and the three third capacitor elements 23 arranged in the second row. The first high-potential extension piece 131 and the second high-potential extension piece 132 are connected via the high-potential connecting piece 133 between a pair of busbars connected to the third capacitor elements 23 arranged in the second row on the second side wall 84 side.

The first low-potential extension piece 141 is provided so as to overlap in the up-down direction Z with the first side wall side half of the three third capacitor elements 23 arranged in the third row and the three third capacitor elements 23 arranged in the second row. The second low-potential extension piece 142 is provided so as to overlap in the up-down direction Z with the third side wall side half of the three third capacitor elements 23 arranged in the first row and the three third capacitor elements 23 arranged in the second row. The first low-potential extension piece 141 and the second low-potential extension piece 142 are connected via a low-potential connecting piece 143 between a pair of busbars connected to the third capacitor elements 23 arranged in the second row on the fourth side wall 86 side.

The insulating plate 160 is provided between the high-potential busbar 130 and the low-potential busbar 140. A first piece 161 is provided between the first high-potential extension piece 131 and the second low-potential extension piece 142. A second piece 162 is provided between the first low-potential extension piece 141 and the second high-potential extension piece 132. A connecting piece 163 is provided between the high-potential connecting piece 133 and the low-potential connecting piece 143. A second low-potential extension piece 142 is provided farther away than the first high-potential extension piece 131 from the half on the third side wall side of the three third capacitor elements 23 arranged in the first row and the three third capacitor elements 23 arranged in the second row. A second high-potential extension piece 132 is provided farther away than the first low-potential extension piece 141 from the half on the first side wall side of the three third capacitor elements 23 arranged in the third row and the three third capacitor elements 23 arranged in the second row.

A high-potential connection terminal 336, which is connected to the high-potential busbar 324, is provided on the first high-potential extension piece 131 and the second high-potential extension piece 132. The high-potential connection terminal 336 extends so as to protrude from the first high-potential extension piece 131 and the second high-potential extension piece 132. A low-potential connection terminal 346, which is connected to the low-potential busbar 325, is provided on the first low-potential extension piece 141 and the second low-potential extension piece 142. The low-potential connection terminal 346 extends so as to protrude from the first low-potential extension piece 141 and the second low-potential extension piece 142.

Further, a first through hole 301 for passing the high-potential busbar 324 and a second through hole 302 for passing the low-potential busbar 325 are provided in the first high-potential extension piece 131 and the second high-potential extension piece 132. A third through hole 303 for passing the high-potential busbar 324 and a fourth through hole 304 for passing the low-potential busbar 325 are provided in the first low-potential extension piece 141 and the second low-potential extension piece 142. Further, a fifth through hole 305 for passing the high-potential busbar 324 and a sixth through hole 306 for passing the low-potential busbar 325 are provided in the first piece 161 and the second piece 162.

The first through hole 301, the third through hole 303, and the fifth through hole 305 are aligned with each other in the up-down direction Z. The second through hole 302, the fourth through hole 304, and the sixth through hole 306 are aligned with each other in the up-down direction Z. The high-potential connection terminal 336 is provided at an edge of the first through hole 301. The high-potential busbar 324 passes through a space where the first through hole 301, the third through hole 303, and the fifth through hole 305 overlap. The high-potential connection terminal 336 and the high-potential busbar 324 are electrically and mechanically connected.

The low-potential connection terminal 346 is provided at an edge of the second through hole 302. The low-potential busbar 325 passes through a space where the second through hole 302, the fourth through hole 304, and the sixth through hole 306 overlap. The low-potential connection terminal 346 and the low-potential busbar 325 are electrically and mechanically connected. With such a structure, the PN busbars 130 and 140 can be electrically connected even to multiple third capacitor modules 20E.

### Fourth Embodiment

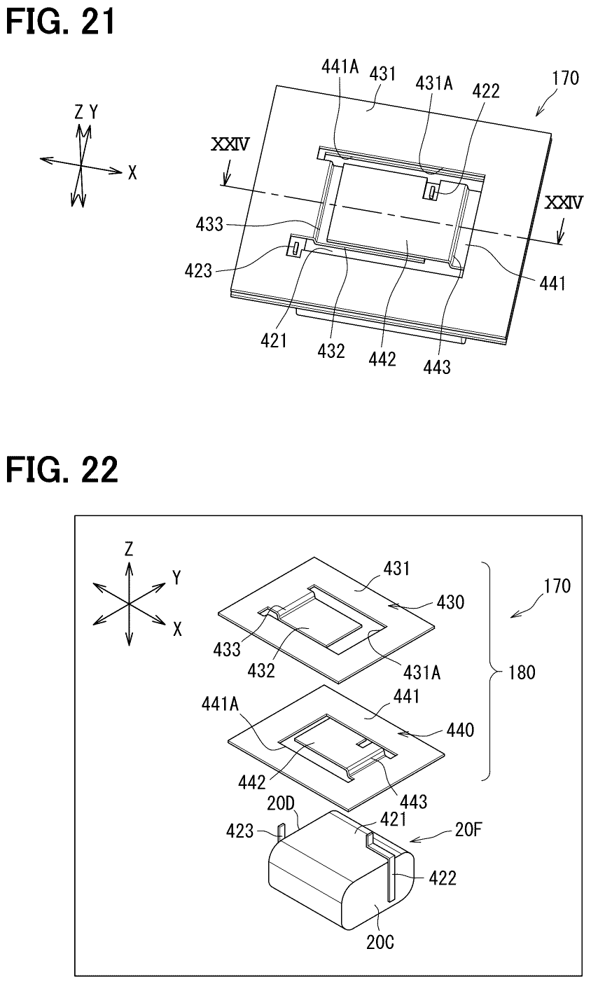

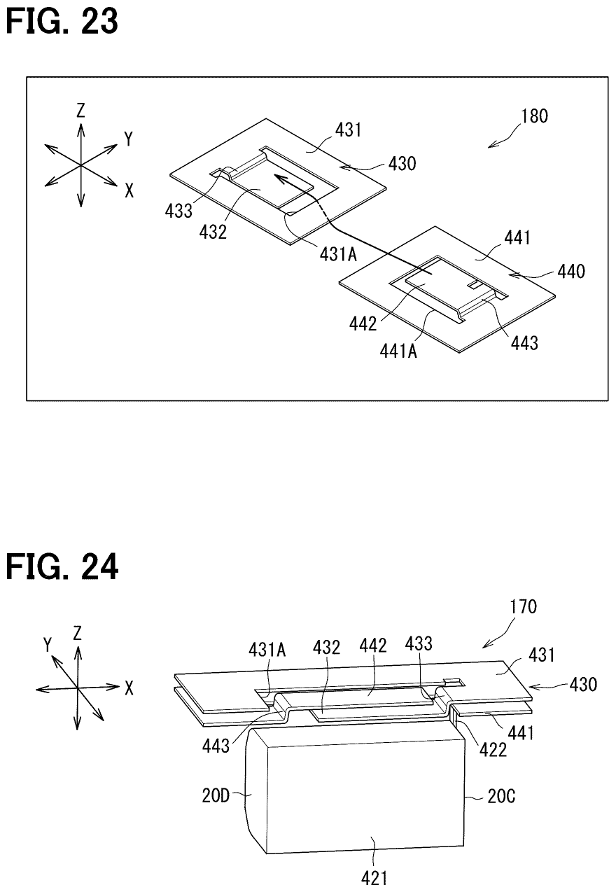

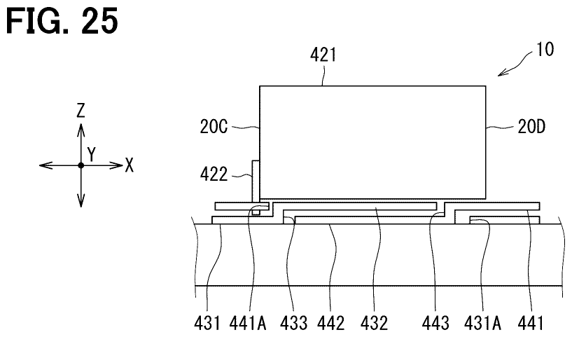

Next, a fourth embodiment will be described. FIG. 21 is a perspective view of a capacitor device 170 according to the fourth embodiment. FIG. 22 is an exploded perspective view of the capacitor device 170 according to the fourth embodiment. FIG. 23 is a schematic diagram illustrating a manufacturing method of a busbar module 180 according to the fourth embodiment. FIG. 24 is a perspective view of the capacitor device 170 according to the fourth embodiment as seen in cross-section along line XXIV-XXIV. FIG. 25 is a cross-sectional view of a power conversion device 10 according to the fourth embodiment. In FIGS. 21 to 25, the configuration of the insulating plate 160 is omitted. The capacitor device 170 and the busbar module 180 according to the fourth embodiment may or may not have the insulating plate 160. Since the fourth embodiment includes components common to the first embodiment, only the components that differ from the first embodiment will be described below. Components not described below are the same as those in the first embodiment.

As an example, a capacitor 20 of the fourth embodiment has a single fourth capacitor module 20F. The number of fourth capacitor modules 20F is not limited to one. The capacitor 20 of the fourth embodiment may have fourth capacitor modules 20F. The fourth capacitor module 20F includes a fourth capacitor element 421, a high-potential busbar 422, and a low-potential busbar 423. The high-potential busbar 422 is connected to the first electrode 20C of the fourth capacitor element 421. The low-potential busbar 423 is connected to the second electrode 20D of the fourth capacitor element 421.

The busbar module 180 overlaps the fourth capacitor module 20F in the up-down direction Z. The busbar module 180 of the fourth embodiment includes a high-potential busbar 430 and a low-potential busbar 440. The high-potential busbar 430 and the low-potential busbar 440 have a plate thickness in the up-down direction Z. The high-potential busbar 430 includes a first high-potential connecting piece 431, a second high-potential piece 432, and a high-potential connecting piece 433. The first high-potential connecting piece 431 is a part that electrically connects the fourth capacitor element 421, the Y-capacitor 40, and the inverter 11 on the high-potential side. In a view in the up-down direction Z, the first high-potential connecting piece 431 forms an annular shape. The first high-potential connecting piece 431 extends annularly around an axis along the up-down direction Z. In other words, the first high-potential connecting piece 431 has a frame shape that surrounds a hole 431A penetrating in the up-down direction Z.

The second high-potential connecting piece 432 is connected to one side of the first high-potential connecting piece 431 via the high-potential coupling piece 433. The second high-potential connecting piece 432 is cantilever-supported by the first high-potential connecting piece 431. The first high-potential connecting piece 431 and the second high-potential connecting piece 432 extend along an XY-plane. In the up-down direction Z, the first high-potential connecting piece 431 is provided farther from the fourth capacitor element 421 than the second high-potential connecting piece 432. The high-potential coupling piece 433 serves the role of connecting the first high-potential connecting piece 431 and the second high-potential connecting piece 432. The first high-potential connecting piece 431, the second high-potential connecting piece 432, and the high-potential coupling piece 433 are integrally connected by the same material.

The low-potential busbar 440 includes a first low-potential connecting piece 441, a second low-potential connecting piece 442, and a low-potential coupling piece 443. The first low-potential connecting piece 441 is a part that electrically connects the fourth capacitor element 421, the Y-capacitor 40, and the inverter 11 on the low-potential side. In a plan view from the up-down direction Z, the first low-potential connecting piece 441 forms a ring shape. The first low-potential connecting piece 441 extends in a ring shape around an axis along the up-down direction Z. The first low-potential connecting piece 441 can also be described as having a frame shape that surrounds a hole 441A penetrating in the up-down direction Z.

On one side of the first low-potential connecting piece 441, the second low-potential connecting piece 442 is connected via a low-potential coupling piece 443. The second low-potential connecting piece 442 is cantilever-supported by the first low-potential connecting piece 441. The first low-potential connecting piece 441 and the second low-potential connecting piece 442 extend along the XY-plane. In the up-down direction Z, the second low-potential connecting piece 442 is provided farther from the fourth capacitor element 421 than the first low-potential connecting piece 441. The low-potential coupling piece 443 serves the role of connecting the first low-potential connecting piece 441 and the second low-potential connecting piece 442. The first low-potential connecting piece 441, the second low-potential connecting piece 442, and the low-potential coupling piece 443 are integrally connected by the same material.

In the busbar module 180, the first high-potential connecting piece 431 and the first low-potential connecting piece 441 overlap in the up-down direction Z. The first high-potential connecting piece 431 is provided farther from the fourth capacitor element 421 than the first low-potential connecting piece 441 in the up-down direction Z. The second high-potential connecting piece 432 and the second low-potential connecting piece 442 overlap in the up-down direction Z. The second low-potential connecting piece 442 is provided farther from the fourth capacitor element 421 than the second high-potential connecting piece 432 in the up-down direction Z. The hole 431A and the hole 441A overlap in the up-down direction Z.

As described above, the high-potential busbar 422 is connected to the first electrode 20C. The low-potential busbar 423 is connected to the second electrode 20D. The high-potential busbar 422 extends in the up-down direction Z. Although not shown in the figures, a hole for passing the high-potential busbar 422 is formed in the second high-potential connecting piece 432. The high-potential busbar 422 that passes through the hole is electrically connected to the second high-potential connecting piece 432. It should be noted that a notch allowing passage of the high-potential busbar 422 is formed in the second low-potential connecting piece 442. Accordingly, after assembling the capacitor device 170, the second high-potential connecting piece 432 and the high-potential busbar 422 can be joined together by welding or the like.

Although not shown in the figures, a hole for passing the low-potential busbar 423 is formed in the first low-potential connecting piece 441. The low-potential busbar 423 that passes through the hole is electrically connected to the first low-potential connecting piece 441. It should be noted that a notch allowing the low-potential busbar 423 to pass through is formed in the first high-potential connecting piece 431. Accordingly, after assembling the capacitor device 170, the first low-potential connecting piece 441 and the low-potential busbar 423 can be joined together by welding or the like.

As shown in FIGS. 24 and 25, a distance between the high-potential heat dissipation plate 432 and the fourth capacitor element 421 in the up-down direction Z, and a distance between the low-potential connecting piece 441 and the fourth capacitor element 421, are equal. In the up-down direction Z, a distance between the low-potential heat dissipation plate 442 and the fourth capacitor element 421, and a distance between the high-potential connecting piece 431 and the low-potential heat dissipation plate 442, are equal. In the up-down direction Z, the low-potential heat dissipation plate 442 and the high-potential connecting piece 431 are provided farther from the fourth capacitor element 421 than the low-potential connecting piece 441 and the high-potential heat dissipation plate 432. Accordingly, heat from the fourth capacitor element 421 is dissipated by the low-potential heat dissipation plate 442 and the high-potential connecting piece 431. The heat dissipation effect of the capacitor element 421 is enhanced. The output of the inverter 11 can be increased.

It should be noted that, in the fourth embodiment, the first high-potential connecting piece 431 corresponds to a first high-potential portion. The first low-potential connecting piece 441 corresponds to a first low-potential portion. The second low-potential connecting piece 442 corresponds to a second low-potential portion. The second high-potential connecting piece 432 corresponds to a second high-potential portion.

The following describes a manufacturing method of the capacitor device 170 and the power conversion device 10 of the fourth embodiment. In the manufacture of the capacitor device 170, the high-potential busbar 430 and the low-potential busbar 440 are arranged such that an open end of the second high-potential connecting piece 432 and an open end of the second low-potential connecting piece 442 face each other. In this state, the second low-potential connecting piece 442 is passed through the hole 431A and stacked on the second high-potential connecting piece 432 in the up-down direction Z.

Next, the high-potential busbar 422 is passed through a hole (not shown) provided in the second high-potential connecting piece 432. The high-potential busbar 422 and the second high-potential connecting piece 432 are electrically connected by welding or the like. The low-potential busbar 423 is passed through a hole (not shown) provided in the first low-potential connecting piece 441. The low-potential busbar 423 and the first low-potential connecting piece 441 are electrically connected by welding or the like. The capacitor device 170 manufactured in this manner is arranged in the case 80 so that the busbar module 180 faces the bottom portion 81. Then, the inverter 11 and the Y-capacitor 40 are electrically connected to the busbar module 180. In this manner, the power conversion device 10 is manufactured.

While the present disclosure has been described with reference to embodiments thereof, it is to be understood that the disclosure is not limited to the embodiments and constructions. To the contrary, the present disclosure is intended to cover various modification and equivalent arrangements. In addition, while the various elements are shown in various combinations and configurations, which are exemplary, other combinations and configurations, including more, less or only a single element, are also within the spirit and scope of the present disclosure.

What is claimed is:

1. A power conversion device comprising:
a capacitor device provided between an electrical component and a switch module, wherein
the capacitor device includes:
capacitor elements arranged in an alignment direction different from a width direction, wherein the alignment direction is a direction in which the electrical component and the switch module are arranged, and each capacitor element has a first electrode and a second electrode on end faces separated in the width direction;
a high-potential busbar electrically connecting first electrodes of the capacitor elements, the electrical component, and the switch module; and
a low-potential busbar electrically connecting second electrodes of the capacitor elements, the electrical component, and the switch module,
the high-potential busbar and the low-potential busbar are provided at positions overlapping the capacitor elements in a plate thickness direction different from the alignment direction and the width direction,
the high-potential busbar has a first high-potential portion and a second high-potential portion,
the low-potential busbar has a first low-potential portion and a second low-potential portion,
the first high-potential portion is provided farther from the capacitor elements than the first low-potential portion in the plate thickness direction, and
the second low-potential portion is provided farther from the capacitor elements than the second high-potential portion in the plate thickness direction.

2. The power conversion device according to claim 1, wherein
the high-potential busbar includes:
a first high-potential extension piece as the second high-potential portion;
a second high-potential extension piece as the first high-potential portion, the first and second high-potential extension pieces being positioned at different locations in the plate thickness direction; and
a high-potential connecting piece extending in the plate thickness direction to connect a part of the first high-potential extension piece and a part of the second high-potential extension piece,
the high-potential connecting piece is arranged alongside a first gap between remaining parts of the first and second high-potential extension pieces,
the low-potential busbar includes:
a first low-potential extension piece as the first low-potential portion;
a second low-potential extension piece as the second low-potential portion, the first and second low-potential extension pieces being positioned at different locations in the plate thickness direction; and
a low-potential connecting piece extending in the plate thickness direction to connect a part of the first low-potential extension piece and a part of the second low-potential extension piece,
the low-potential connecting piece is arranged alongside a second gap between remaining parts of the first and second low-potential extension pieces,
the low-potential connecting piece passes through the first gap, and
the high-potential connecting piece passes through the second gap.

3. The power conversion device according to claim 2, wherein
the capacitor elements include a first capacitor element and a second capacitor element,
the first high-potential extension piece and the second low-potential extension piece overlap the first capacitor element in the plate thickness direction,
the second high-potential extension piece and the first low-potential extension piece overlap the second capacitor element in the plate thickness direction,
the second low-potential extension piece is provided farther from the first capacitor element than the first high-potential extension piece in the plate thickness direction, and
the second high-potential extension piece is provided farther from the second capacitor element than the first low-potential extension piece in the plate thickness direction.

4. The power conversion device according to claim 3, wherein
the first capacitor element and the second capacitor element are arranged such that the first electrode of the first capacitor element and the second electrode of the second capacitor element, and the second electrode of the first capacitor element and the first electrode of the second capacitor element, are aligned in the alignment direction, and
the first high-potential extension piece and the second low-potential extension piece are connected to a battery via the electrical component.

5. The power conversion device according to claim 1, further comprising:
a case housing the capacitor device, the switch module, and the electrical component; and
a heat dissipation member provided at a bottom portion of the case, wherein
the bottom portion has a cooling passage therein through which a coolant for cooling the capacitor device flows,
the capacitor device is provided in the case such that the high-potential busbar and the low-potential busbar face the bottom portion in the plate thickness direction, and
the second high-potential extension piece and the second low-potential extension piece are in contact with the heat dissipation member.

6. The power conversion device according to claim 5, wherein
each of the first high-potential extension piece and the second high-potential extension piece has:
a high-potential overlapping portion overlapping at least one of the capacitor elements in the plate thickness direction; and
a high-potential connection terminal provided at an end of the high-potential overlapping portion in the width direction, protruding from the high-potential overlapping portion, and electrically connected to the first electrode,
each of the first low-potential extension piece and the second low-potential extension piece has:
a low-potential overlapping portion overlapping at least one of the capacitor elements in the plate thickness direction; and
a low-potential connection terminal provided at an end of the low-potential overlapping portion in the width direction, protruding from the low-potential overlapping portion, and electrically connected to the second electrode,
the bottom portion has a high-potential recess housing the high-potential connection terminal and a low-potential recess housing the low-potential connection terminal,
the heat dissipation member is provided inside each of the high-potential recess and the low-potential recess, and
the high-potential connection terminal and the low-potential connection terminal are in contact with the heat dissipation member.

7. The power conversion device according to claim 3, wherein
the first capacitor element and the second capacitor element are arranged such that the first electrode of the first capacitor element and the first electrode of the second capacitor element, and the second electrode of the first capacitor element and the second electrode of the second capacitor element, are aligned in the alignment direction, and
the first high-potential extension piece and the second low-potential extension piece are connected to a battery via the electrical component.

8. The power conversion device according to claim 7, wherein
each of the first high-potential extension piece and the second high-potential extension piece has:
a high-potential overlapping portion overlapping the first capacitor element or the second capacitor element in the plate thickness direction; and
a high-potential connection terminal provided at an end of the high-potential overlapping portion in the width direction, protruding from the high-potential overlapping portion, and electrically connected to the first electrode;
each of the first low-potential extension piece and the second low-potential extension piece has:
a low-potential overlapping portion overlapping the first capacitor element or the second capacitor element in the plate thickness direction; and
a low-potential connection terminal provided at an end of the low-potential overlapping portion in the width direction, protruding from the low-potential overlapping portion, and electrically connected to the second electrode,
the second high-potential extension piece is provided with a high-potential notch through which a part of the low-potential connection terminal passes, and
the second low-potential extension piece is provided with a low-potential notch through which a part of the high-potential connection terminal passes.

9. The power conversion device according to claim 2, further comprising:
a high-potential busbar connected to the first electrode of each capacitor element and extending in the plate thickness direction; and
a low-potential busbar connected to the second electrode of each capacitor element and extending in the plate thickness direction, wherein
each of the first high-potential extension piece and the second high-potential extension piece has:
a high-potential overlapping portion overlapping at least one of the capacitor elements in the plate thickness direction; and
a high-potential connection terminal protruding from the high-potential overlapping portion and electrically connected to the high-potential busbar,
each of the first low-potential extension piece and the second low-potential extension piece has:
a low-potential overlapping portion overlapping at least one of the capacitor elements in the plate thickness direction; and
a low-potential connection terminal protruding from the low-potential overlapping portion and electrically connected to the low-potential busbar,
the high-potential overlapping portion has a first through hole through which the high-potential busbar passes and a second through hole through which the low-potential busbar passes,
the low-potential overlapping portion has a third through hole through which the high-potential busbar passes and a fourth through hole through which the low-potential busbar passes,
the high-potential busbar passing through the first and third through holes is connected to the high-potential connection terminal, and
the low-potential busbar passing through the second and fourth through holes is connected to the low-potential connection terminal.

10. A capacitor device comprising:
capacitor elements each having a first electrode and a second electrode on end faces separated in a width direction, the capacitor elements being arranged in an alignment direction different from the width direction;
a high-potential busbar connected to the first electrode; and
a low-potential busbar connected to the second electrode, wherein
the high-potential busbar and the low-potential busbar are provided at positions overlapping the capacitor elements in a plate thickness direction different from the alignment direction and the width direction,
the high-potential busbar has a first high-potential portion and a second high-potential portion,
the low-potential busbar has a first low-potential portion and a second low-potential portion,
the first high-potential portion is provided farther from the capacitor elements than the first low-potential portion in the plate thickness direction, and
the second low-potential portion is provided farther from the capacitor elements than the second high-potential portion in the plate thickness direction.

11. A power conversion device comprising:
a capacitor device provided between an electrical component and a switch module, wherein
the capacitor device includes:
a capacitor element having a first electrode and a second electrode separated in a width direction;
a high-potential busbar electrically connecting the first electrode, the electrical component, and the switch module; and
a low-potential busbar electrically connecting the second electrode, the electrical component, and the switch module, wherein
the high-potential busbar and the low-potential busbar are provided at positions overlapping the capacitor element in a plate thickness direction different from the width direction,
the high-potential busbar has a first high-potential portion and a second high-potential portion,
the low-potential busbar has a first low-potential portion and a second low-potential portion,
the first high-potential portion is provided farther from the capacitor element than the first low-potential portion in the plate thickness direction, and
the second low-potential portion is provided farther from the capacitor element than the second high-potential portion in the plate thickness direction.

12. A capacitor device comprising:
a capacitor element having a first electrode and a second electrode on end faces separated in a width direction;
a high-potential busbar connected to the first electrode; and
a low-potential busbar connected to the second electrode, wherein
the high-potential busbar and the low-potential busbar are provided at positions overlapping the capacitor element in a plate thickness direction different from the width direction,
the high-potential busbar has a first high-potential portion and a second high-potential portion,
the low-potential busbar has a first low-potential portion and a second low-potential portion,
the first high-potential portion is provided farther from the capacitor element than the first low-potential portion in the plate thickness direction, and
the second low-potential portion is provided farther from the capacitor element than the second high-potential portion in the plate thickness direction.
